(19) United States
(12) Patent Application Publication
(10) Pub. No.: US 2023/0035447 A1
(43) Pub. Date: Feb. 2, 2023

(54) SUBSTRATE TREATMENT METHOD AND SUBSTRATE TREATMENT DEVICE

(71) Applicant: SCREEN Holdings Co., Ltd., Kyoto (JP)

(72) Inventors: Shigeru YAMAMOTO, Kyoto (JP); Kenji EDAMITSU, Kyoto (JP); Daiki FUJII, Kyoto (JP); Keiji IWATA, Kyoto (JP); Kenichi ITO, Kyoto (JP); Yuya KAWAI, Kyoto (JP)

(73) Assignee: SCREEN Holdings Co., Ltd., Kyoto (JP)

(21) Appl. No.: 17/876,540

(22) Filed: Jul. 29, 2022

(30) Foreign Application Priority Data
Jul. 30, 2021 (JP) 2021-125535

(51) Int. Cl. B05D 5/08; B08B 3/02; B08B 3/08; B08B 3/04

(52) U.S. Cl. CPC B05D 5/08; B08B 3/022; B08B 3/08; B08B 3/041

(57) ABSTRACT

A substrate treatment method includes a first gas treating step, a water-repellency treatment step, and a spraying step. In the first gas treating step, a first gas is supplied to the substrate inside the chamber in a state in which the inside of the chamber is decompressed. The first gas includes gas of an organic solvent. The water-repellency treatment step is executed after the first gas treating step. In the water-repellency treatment step, the inside of the chamber is in the decompressed state, and a water-repellent agent is supplied to the substrate inside the chamber. The spraying step is executed after the water-repellency treatment step. In the spraying step, the inside of the chamber is in the decompressed state, and a first liquid is sprayed over the substrate inside the chamber. The first liquid includes liquid of an organic solvent.

### CROSS-REFERENCE TO RELATED APPLICATION

This application claims the priority benefit of Japan application serial no. 2021-125535, filed on Jul. 30, 2021. The entirety of the above-mentioned patent application is hereby incorporated by reference herein and made a part of this specification.

### BACKGROUND

### Technical Field

The disclosure relates to a substrate treatment method and a substrate treatment device. Examples of a substrate include semiconductor wafers, substrates for liquid crystal displays, substrates for organic electroluminescence (EL), substrates for flat panel displays (FPD), substrates for optical displays, substrates for magnetic disks, substrates for optical discs, substrates for magneto-optical discs, substrates for photomasks, and substrates for solar batteries.

### Description of Related Art

Japanese Patent Laid-Open No. 2018-56155 discloses a substrate treatment method for treating a substrate accommodated inside a chamber. The substrate treatment method has a first step, a second step, and a third step. In the first step, vapor of isopropyl alcohol is supplied to a substrate in a state in which the inside of the chamber is decompressed (decompressed state). In the second step, a hydrophobizing agent is supplied to a substrate in a state in which the inside of the chamber is decompressed. A hydrophobizing agent causes a surface of a substrate to be hydrophobic. In the third step, vapor of isopropyl alcohol is supplied to a substrate in a state in which the inside of the chamber is decompressed. In the third step, a hydrophobizing agent is replaced by isopropyl alcohol on a substrate.

### SUMMARY

### Technical Problem

In substrate treatment methods in the related art, many particles may adhere to a substrate. Particles on a substrate degrade cleanness of a substrate. Particles on a substrate degrade treatment quality of a substrate.

The disclosure has been made in consideration of such circumstances and provides a substrate treatment method and a substrate treatment device capable of reducing particles on a substrate.

### Solution to Problem

The inventors have achieved the following knowledge as a result of intensive studies for resolving the foregoing problems. In a second step of a substrate treatment method in the related art, a hydrophobizing agent comes into contact with a substrate and isopropyl alcohol on the substrate. For this reason, particles may be generated on the substrate. In addition, an unreacted portion of a hydrophobizing agent may remain on a substrate as it is and this may become residual particles. In a third step of the substrate treatment method in the related art, isopropyl alcohol supplied to a substrate is in a gas phase. Thus, a substrate receives a small quantity of isopropyl alcohol in the third step. For example, a substrate receives a small mass of isopropyl alcohol in the third step. Since a substrate receives a small quantity of isopropyl alcohol, particles on the substrate may not be appropriately removed. As a result, many particles may remain on the substrate.

Hence, the inventors have reviewed changing the third step. In the changed third step, instead of supplying vapor of isopropyl alcohol to a substrate, a substrate is dipped into liquid of isopropyl alcohol stored in a treatment tank. According to the changed third step, particles on a substrate may be favorably removed.

However, the inventors have found that the changed third step has new problems. Specifically, it is difficult to execute the changed third step in a state in which the inside of a chamber is decompressed. It is difficult to prepare a treatment tank storing isopropyl alcohol in a state in which the inside of the chamber is decompressed.

The disclosure has been obtained through further intensive studies based on the knowledge and has the following constitutions. That is, the disclosure provides a substrate treatment method for simultaneously treating a plurality of substrates accommodated in one chamber. The substrate treatment method includes a first gas treating step of supplying a first gas including gas of an organic solvent to the substrate inside the chamber in a state in which the inside of the chamber is decompressed, a water-repellency treatment step of supplying a water-repellent agent to the substrate inside the chamber in a state in which the inside of the chamber is decompressed after the first gas treating step, and a spraying step of spraying a first liquid including liquid of an organic solvent over the substrate inside the chamber in a state in which the inside of the chamber is decompressed after the water-repellency treatment step.

In the substrate treatment method, a plurality of substrates accommodated in one chamber is simultaneously treated. The substrate treatment method includes the first gas treating step, the water-repellency treatment step, and the spraying step. The first gas treating step, the water-repellency treatment step, and the spraying step are executed in this order. In the first gas treating step, the water-repellency treatment step, and the spraying step, the inside of the chamber is in a decompressed. In the first gas treating step, the first gas is supplied to the substrate inside the chamber. The first gas includes gas of an organic solvent. The substrate receives the organic solvent of the first gas. The gas of the organic solvent in the first gas is dew-condensed on a surface of the substrate and changes to liquid of the organic solvent on the surface of the substrate. In the water-repellency treatment step, the water-repellent agent is supplied to the substrate inside the chamber. The substrate receives the water-repellent agent. The water-repellent agent causes the surface of the substrate to be water repellent. In the water-repellency treatment step, the water-repellent agent comes into contact with the substrate and the organic solvent on the substrate. For this reason, particles may be generated on the substrate. In the spraying step, the first liquid is sprayed over the substrate inside the chamber. Even in a state in which the inside of the chamber is decompressed, it is easy to spray the first liquid over the substrate. The first liquid includes liquid of the organic solvent. The substrate receives the first liquid. Since the first liquid is a liquid, the substrate receives a relatively large quantity of the first liquid in the spraying step. For example, the substrate receives a relatively large mass of the first liquid in the spraying step. Thus, in the spraying step, the first liquid favorably removes particles on the substrate. Therefore, the quantity of particles on the substrate is favorably reduced. As a result, the cleanness of the substrate is favorably improved. The treatment quality of the substrate is favorably improved.

As above, the substrate treatment method is capable of favorably reducing particles on a substrate.

According to the substrate treatment method described above, it is preferable that in the spraying step, at least any of droplets of the first liquid and mist of the first liquid be sprayed. In the spraying step, the first liquid is efficiently supplied to the substrate.

According to the substrate treatment method described above, it is preferable that in the spraying step, the first liquid be sprayed through at least any of shower head nozzles and two-fluid nozzles. In the spraying step, the first liquid is efficiently supplied to the substrate.

According to the substrate treatment method described above, it is preferable that in the spraying step, the substrate be further vertically moved or swung inside the chamber. In the spraying step, the first liquid adheres more uniformly to the entire substrate.

According to the substrate treatment method described above, it is preferable that the spraying step include at least any of a first spraying step and a second spraying step. It is preferable that in the first spraying step, a diluted organic solvent be sprayed as the first liquid. It is preferable that in the second spraying step, an undiluted organic solvent be sprayed as the first liquid. In the first spraying step, the first liquid is a diluted organic solvent. For this reason, the quantity of the organic solvent used in the first spraying step is favorably reduced. In the second spraying step, the first liquid is an undiluted organic solvent. For this reason, in the second spraying step, the first liquid has a small surface tension. Thus, in the second spraying step, the first liquid does not exert a significant force to the substrate. As a result, in the second spraying step, the substrate is favorably protected.

According to the substrate treatment method described above, it is preferable to further include a second gas treating step of supplying a second gas including gas of an organic solvent to the substrate inside the chamber in a state in which the inside of the chamber is decompressed after the water-repellency treatment step. In the second gas treating step, the entire substrate is exposed to the second gas. The second gas includes gas of an organic solvent. For this reason, in the second gas treating step, the organic solvent derived from the second gas quickly adheres to the entire substrate. In the second gas treating step, the organic solvent derived from the second gas uniformly adheres to the entire substrate. Thus, in the second gas treating step, uniformity in cleanness of the substrate throughout the entire substrate is improved.

According to the substrate treatment method described above, it is preferable that a quantity of the first liquid supplied in the spraying step be larger than a quantity of the second gas supplied in the second gas treating step. In the spraying step, the substrate receives a larger quantity of the first liquid. Thus, in the spraying step, the first liquid more appropriately removes particles on the substrate.

According to the substrate treatment method described above, it is preferable that a time over which the spraying step is executed be longer than a time over which the second gas treating step is executed. In the spraying step, the substrate receives a larger quantity of the first liquid. Thus, in the spraying step, particles on the substrate are more favorably removed.

According to the substrate treatment method described above, it is preferable to further include a first dipping step of dipping the substrate into a second liquid stored in a treatment tank installed inside the chamber before the first gas treating step. It is preferable that in the first gas treating step, the water-repellency treatment step, and the spraying step, the substrate be positioned above the treatment tank. The substrate treatment method includes the first dipping step. In the first dipping step, the treatment tank stores the second liquid. After the first dipping step, the first gas treating step, the water-repellency treatment step, and the spraying step are executed. In the first gas treating step, the water-repellency treatment step, and the spraying step, the inside of the chamber is in a decompressed state. For this reason, the inside of the chamber is in a decompressed state until the spraying step after the first dipping step. When the inside of the chamber is in a decompressed state, it is difficult to discharge the second liquid to the outside of the chamber. Thus, when the inside of the chamber is in a decompressed state, it is difficult for the second liquid to be replaced by the first liquid in the treatment tank. Therefore, it is difficult to use the treatment tank in order to supply the first liquid to the substrate until the spraying step after the first dipping step. In the spraying step, the first liquid is sprayed over the substrate without using the treatment tank. For this reason, the first dipping step does not limit execution of the spraying step. Even when the substrate treatment method includes the first dipping step, it is easy to execute the spraying step. Instead, when the substrate treatment method includes the first dipping step, the spraying step is extremely useful.

Moreover, in the first gas treating step, the water-repellency treatment step, and the spraying step, the substrate is positioned above the treatment tank. For this reason, in the first gas treating step, the substrate favorably receives the first treatment gas. In the water-repellency treatment step, the substrate favorably receives the water-repellent agent. In the spraying step, the substrate favorably receives the first liquid.

According to the substrate treatment method described above, it is preferable to further include a first pressurizing step of pressurizing the inside of the chamber from a decompressed state to an atmospheric pressure state after the spraying step, and a first liquid discharging step of maintaining the inside of the chamber in an atmospheric pressure state and discharging the second liquid to the outside of the chamber after the first pressurizing step. The first pressurizing step is executed after the spraying step and before the first liquid discharging step. In the first pressurizing step, the inside of the chamber is pressurized from a decompressed state to an atmospheric pressure state. For this reason, in the first liquid discharging step, it is easy to maintain the inside of the chamber in an atmospheric pressure state. When the inside of the chamber is in an atmospheric pressure state, the pressure of gas inside the chamber is close to the pressure of gas outside the chamber. For this reason, in the first liquid discharging step, it is easy to discharge the second liquid inside the chamber to the outside of the chamber.

According to the substrate treatment method described above, it is preferable that in the first liquid discharging step, a liquid discharge tube which communicates with and is connected to any of the chamber and the treatment tank be open to atmospheric air outside the chamber, and the second liquid be discharged to the outside of the chamber through the liquid discharge tube. In the first liquid discharging step, the liquid discharge tube is open to the atmospheric air outside the chamber. As described above, in the first liquid discharging step, the inside of the chamber is in an atmospheric pressure state. Thus, in the first liquid discharging step, it is easy to discharge the second liquid inside the chamber to the outside of the chamber through the liquid discharge tube.

Here, for example, the second liquid inside the chamber includes the second liquid stored in the treatment tank. When the liquid discharge tube communicates with and is connected to the treatment tank, the second liquid stored in the treatment tank is discharged to the outside of the chamber through the liquid discharge tube. For example, the second liquid inside the chamber includes the second liquid which has been released from the treatment tank and has been accumulated in the chamber. When the liquid discharge tube communicates with and is connected to the chamber, the second liquid accumulated in the chamber is discharged to the outside of the chamber through the liquid discharge tube.

According to the substrate treatment method described above, it is preferable that in the first pressurizing step, mixed gas including an organic solvent and inert gas be supplied to a substrate inside the chamber. The inert gas of the mixed gas quickly pressurizes the inside of the chamber from a decompressed state to an atmospheric pressure state. The organic solvent of the mixed gas adheres to the substrate inside the chamber and moistens the substrate. For this reason, in the first pressurizing step, the substrate does not dry. In summary, in the first pressurizing step, the inside of the chamber is quickly pressurized from a decompressed state to an atmospheric pressure state without causing the substrate inside the chamber to dry.

According to the substrate treatment method described above, it is preferable that the mixed gas include at least any of gas of the organic solvent and liquid of the organic solvent. When the mixed gas includes gas of the organic solvent, the gas of the organic solvent in the mixed gas is dew-condensed on the surface of the substrate and changes to liquid of the organic solvent on the surface of the substrate. When the mixed gas includes liquid of the organic solvent, the liquid of the organic solvent in the mixed gas adheres to the surface of the substrate. Even when the mixed gas includes gas of the organic solvent, or even when the mixed gas includes liquid of the organic solvent, the organic solvent derived from the mixed gas favorably moistens the substrate. Thus, the mixed gas favorably prevents the substrate from drying.

According to the substrate treatment method described above, it is preferable to further include a second dipping step of dipping the substrate into a third liquid stored in the treatment tank after the first liquid discharging step. In the second dipping step, the third liquid more favorably removes particles on the substrate. Thus, particles on the substrate are more favorably reduced.

According to the substrate treatment method described above, it is preferable that an atmosphere inside the chamber include an organic solvent until the substrate is dipped into the third liquid after the first pressurizing step. The organic solvent included in the atmosphere inside the chamber moistens the substrate until the substrate is dipped into the third liquid after the first pressurizing step. Thus, the substrate does not dry until the second dipping step after the first pressurizing step. The substrate does not dry after the spraying step and before the second dipping step. Therefore, in the second dipping step, the substrate is treated with appropriate quality.

According to the substrate treatment method described above, it is preferable that the third liquid be any of a diluted organic solvent and deionized water. When the third liquid is a diluted organic solvent, the third liquid appropriately removes particles on the substrate. When the third liquid is deionized water as well, the third liquid appropriately removes particles on the substrate.

The disclosure provides a substrate treatment device including a chamber that accommodates a plurality of substrates; a decompression unit that decompresses the inside of the chamber; a first supply unit that supplies a first gas including gas of an organic solvent to the substrate inside the chamber; a second supply unit that supplies a water-repellent agent to the substrate inside the chamber; a spray unit that sprays a first liquid including liquid of an organic solvent over the substrate inside the chamber; and a control part that controls the decompression unit, the first supply unit, the second supply unit, and the spray unit to execute first gas treatment, water-repellency treatment, and spraying treatment. In the first gas treatment, the first supply unit supplies the first gas to the substrate in a state in which the inside of the chamber is decompressed by the decompression unit. In the water-repellency treatment, the second supply unit supplies the water-repellent agent to the substrate in a state in which the inside of the chamber is decompressed by the decompression unit. In the spraying treatment, the spray unit sprays the first liquid over the substrate in a state in which the inside of the chamber is decompressed by the decompression unit.

The control part is constituted to execute the first gas treatment, the water-repellency treatment, and the spraying treatment. In the first gas treatment, the water-repellency treatment, and the spraying treatment, the decompression unit causes the inside of the chamber to be in a decompressed state. In the first gas treatment, the first supply unit supplies the first gas to the substrate inside the chamber. The first gas includes gas of an organic solvent. The substrate receives the organic solvent of the first gas. In the water-repellency treatment, the second supply unit supplies the water-repellent agent to the substrate inside the chamber. The substrate receives the water-repellent agent. The water-repellent agent causes the surface of the substrate to be water repellent. In the water-repellency treatment, the water-repellent agent comes into contact with the substrate and the organic solvent on the substrate. For this reason, particles may be generated on the substrate. In the spraying treatment, the spray unit sprays the first liquid over the substrate inside the chamber. Even in a state in which the inside of the chamber is decompressed, the spray unit can easily spray the first liquid over the substrate. The first liquid includes liquid of the organic solvent. The substrate receives the first liquid. The substrate receives a relatively large quantity of the first liquid in the spraying treatment. For example, the substrate receives a relatively large mass of the first liquid in the spraying treatment. Thus, in the spraying treatment, the first liquid favorably removes particles on the substrate. Therefore, the quantity of particles on the substrate is favorably reduced. As a result, the cleanness of the substrate is favorably improved. The treatment quality of the substrate is favorably improved.

As above, the substrate treatment device is capable of favorably reducing particles on a substrate.

### BRIEF DESCRIPTION OF THE DRAWINGS

Several forms which are currently preferred are illustrated in order to describe the disclosure. However, it should be understood that the disclosure is not limited to the illustrated constitutions and measures.

FIG. 1 is a front view illustrating the inside of a substrate treatment device of a first embodiment.

FIG. 2 is a control block diagram of the substrate treatment device.

FIG. 3 is a flowchart showing a procedure of a substrate treatment method of the first embodiment.

FIGS. 4A to 4E are views each of which schematically illustrates the substrate treatment device performing the substrate treatment method of the first embodiment.

FIG. 5 is a front view illustrating the inside of the substrate treatment device of a second embodiment.

FIG. 6 is a flowchart showing a procedure of the substrate treatment method of the second embodiment.

FIG. 7 is another flowchart showing a procedure of the substrate treatment method of the second embodiment.

FIGS. 8A to 8E are views each of which schematically illustrates the substrate treatment device performing the substrate treatment method of the second embodiment.

FIGS. 9A to 9E are views each of which schematically illustrates the substrate treatment device performing the substrate treatment method of the second embodiment.

FIGS. 10A to 10E are views each of which schematically illustrates the substrate treatment device performing the substrate treatment method of the second embodiment.

FIGS. 11A to 11C are views each of which schematically illustrates the substrate treatment device performing the substrate treatment method of the second embodiment.

### DESCRIPTION OF THE EMBODIMENT

Hereinafter, a substrate treatment method and a substrate treatment device of the disclosure will be described with reference to the drawings.

### 1. First Embodiment

### 1-1. Overview of Substrate Treatment Device

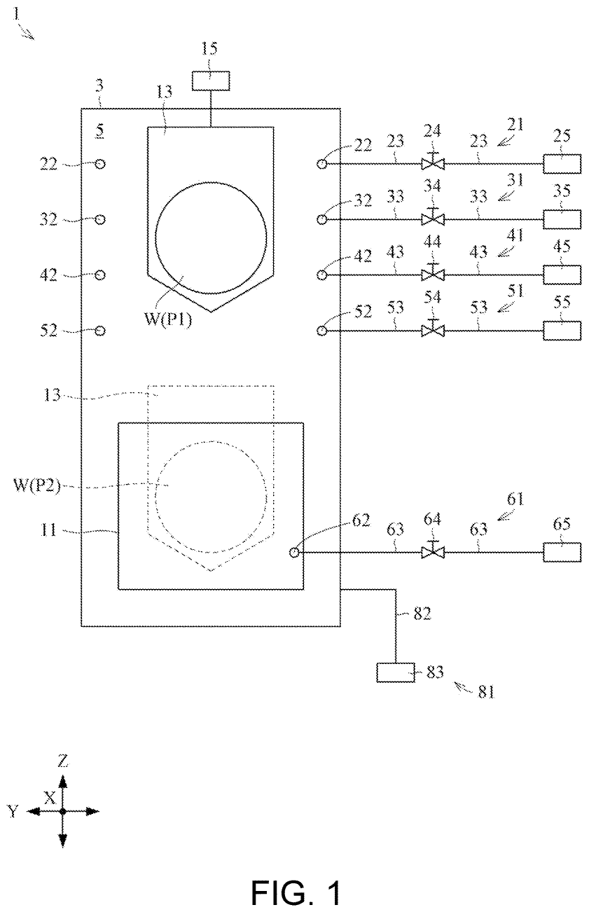

FIG. 1 is a front view illustrating the inside of a substrate treatment device 1 of a first embodiment. The substrate treatment device 1 performs treatment of a substrate W. The treatment performed by the substrate treatment device 1 includes drying treatment. The treatment performed by the substrate treatment device 1 may further include washing treatment. The substrate treatment device 1 is classified into a batch type. The substrate treatment device 1 simultaneously performs treatment of a plurality of substrates W.

Examples of the substrate W include semiconductor wafers, substrates for liquid crystal displays, substrates for organic electroluminescence (EL), substrates for flat panel displays (FPD), substrates for optical displays, substrates for magnetic disks, substrates for optical discs, substrates for magneto-optical discs, substrates for photomasks, and substrates for solar batteries.

The substrate W has a flat plate shape. The substrate W has substantially a circular shape in a front view.

The substrate W has a surface. The surface of the substrate W includes at least any of a silicon oxide film, a polysilicon film, a silicon nitride film, and a metal film.

Although illustration is omitted, the substrate W has a pattern. The pattern is formed on the surface of the substrate W. The pattern has an uneven shape. The surface of the substrate W on which the pattern is formed will be referred to as a pattern formation surface.

The substrate treatment device 1 includes a chamber 3. The chamber 3 accommodates a plurality of substrates W. The chamber 3 simultaneously accommodates a plurality of substrates W. The substrate W is disposed inside the chamber 3. Specifically, the chamber 3 is a container in which a space 5 is partitioned. The space 5 corresponds to the inside of the chamber 3. The substrate W is disposed in the space 5.

The chamber 3 is constituted to be able to be opened and closed. When the chamber 3 is opened, the space 5 is open. When the chamber 3 is opened, the chamber 3 allows the substrate W to move between the space 5 and the outside of the chamber 3. When the chamber 3 is closed, the space 5 is sealed. That is, the chamber 3 is constituted to be able to be sealed.

The substrate treatment device 1 includes a treatment tank 11. The treatment tank 11 is installed inside the chamber 3. The treatment tank 11 stores a treatment liquid. The treatment tank 11 is open upward.

The substrate treatment device 1 includes a holding part 13. The holding part 13 is installed inside the chamber 3. The holding part 13 simultaneously holds a plurality of substrates W. The holding part 13 holds each of the substrates W substantially in a vertical posture. When the holding part 13 holds the substrate W, the pattern formation surface of the substrate W is substantially vertical. When the holding part 13 holds a plurality of substrates W, the plurality of substrates W is arranged in a row in a direction X. The direction X is a horizontal direction. The direction X is substantially perpendicular to the pattern formation surface of the substrate W.

In FIG. 1, in addition to the direction X, a direction Y and a direction Z are indicated. The direction Y is a horizontal direction. The direction Y is perpendicular to the direction X. The direction Z is a vertical direction. The direction Z is perpendicular to the direction X. The direction Z is perpendicular to the direction Y. The direction Z will be suitably referred to as a vertical direction Z.

The substrate treatment device 1 includes a lifting/lowering mechanism 15. The lifting/lowering mechanism 15 lifts and lowers the holding part 13. For example, the lifting/lowering mechanism 15 moves the holding part 13 in the vertical direction Z. When the lifting/lowering mechanism 15 lifts and lowers the holding part 13, the substrate W held by the holding part 13 is integrally lifted and lowered with the holding part 13.

The lifting/lowering mechanism 15 moves the substrate W between a first position P1 and a second position P2. In FIG. 1, the substrate W at the first position P1 is indicated by a solid line. In FIG. 1, the substrate W at the second position P2 is indicated by a dashed line. The first position P1 is positioned inside the chamber 3. The first position P1 is positioned above the treatment tank 11. When the substrate W is positioned at the first position P1, the entire substrate W does not come into contact with the treatment liquid inside the treatment tank 11. The second position P2 is positioned inside the chamber 3. The second position P2 is positioned below the first position P1. The second position P2 is positioned inside the treatment tank 11. When the substrate W is positioned at the second position P2, the entire substrate W is dipped into the treatment liquid inside the treatment tank 11.

The substrate treatment device 1 includes supply units 21, 31, 41, 51, and 61. The supply unit 21 supplies the inert gas to the chamber 3. The supply unit 31 supplies a water-repellent agent to the chamber 3. The supply unit 41 supplies treatment gas to the chamber 3. The supply unit 51 supplies a first liquid to the chamber 3. The supply unit 61 supplies a second liquid to the treatment tank 11.

When the substrate W is positioned at the first position P1, the supply unit 21 supplies the inert gas to the substrate W. When the substrate W is positioned at the first position P1, the supply unit 31 supplies the water-repellent agent to the substrate W. When the substrate W is positioned at the first position P1, the supply unit 41 supplies the treatment gas to the substrate W. When the substrate W is positioned at the first position P1, the supply unit 51 supplies the first liquid to the substrate W.

The supply unit 41 is an example of a first supply unit according to the disclosure. The supply unit 31 is an example of a second supply unit according to the disclosure. The supply unit 51 is an example of a spray unit according to the disclosure.

For example, the inert gas supplied by the supply unit 21 is nitrogen gas.

The water-repellent agent supplied by the supply unit 31 will be described. The water-repellent agent causes the surface of the substrate W to be water repellent. The water-repellent agent modifies the surface of the substrate W to be water repellent. The water-repellent agent increases a contact angle between the surface of the substrate W and water. The water-repellent agent forms a water-repellent film on the surface of the substrate W. The surface of the substrate W is coated with the water-repellent agent. The water-repellent agent is also referred to as an interfacial modifier. The water-repellent agent is also referred to as a hydrophobizing agent.

For example, the water-repellent agent includes at least any of a silicon-based water-repellent agent and a metal-based water-repellent agent. The silicon-based water-repellent agent causes silicon to be water repellent. The silicon-based water-repellent agent causes a compound including silicon to be water repellent. For example, the silicon-based water-repellent agent is a silane coupling agent. For example, a silane coupling agent includes at least one of hexamethyldisilazane (HMDS), tetramethylsilane (TMS), fluorinated alkylchlorosilane, alkyl disilazane, and a non-chloro-based water-repellent agent. For example, a non-chloro-based water-repellent agent includes at least one of dimethylsilyldimethylamine, dimethylsilyldiethylamine, hexamethyldisilazane, tetramethyldisilazane, bis(dimethylamino)dimethylsilane, N,N-dimethylaminotrimethylsilane, N-(trimethylsilyl)dimethylamine, and an organosilane compound. The metal-based water-repellent agent causes a metal to be water repellent. The metal-based water-repellent agent causes a compound including a metal to be water repellent. For example, the metal-based water-repellent agent includes at least one of amine having a hydrophobic group, and an organic silicon compound.

The water-repellent agent may further include a solvent. For example, a solvent may also be obtained by diluting at least any of a silicon-based water-repellent agent and a metal-based water-repellent agent. It is preferable that the solvent have phase solubility with respect to an organic solvent. For example, a solvent includes at least any of isopropyl alcohol (IPA) and propylene glycol monomethyl ether acetate (PGMEA).

The water-repellent agent includes at least any of gas of the water-repellent agent and liquid of the water-repellent agent. The supply unit 31 supplies at least any of gas of the water-repellent agent and liquid of the water-repellent agent. For example, the gas of the water-repellent agent is vapor of the water-repellent agent.

The treatment gas supplied by the supply unit 41 will be described. The treatment gas includes gas of the organic solvent. For example, gas of the organic solvent is vapor of the organic solvent. For example, the concentration of the organic solvent in the treatment gas is high. For example, the treatment gas practically consists of only gas of the organic solvent. For example, the treatment gas practically includes no water (water vapor). It is preferable that the organic solvent of the treatment gas be hydrophilic. For example, the organic solvent of the treatment gas is isopropyl alcohol (IPA).

The treatment gas includes no water-repellent agent.

The first liquid supplied by the supply unit 51 will be described. The first liquid includes liquid of the organic solvent. For example, the first liquid practically consists of only liquid of the organic solvent. For example, the first liquid is an undiluted solution of an organic solvent. For example, the first liquid is liquid of an undiluted organic solvent. For example, the first liquid practically includes no water. Alternatively, the first liquid is liquid of a diluted organic solvent. For example, the first liquid is an organic solvent diluted with deionized water. For example, the first liquid is a mixed liquid of deionized water and an organic solvent. For example, the organic solvent of the first liquid is isopropyl alcohol (IPA).

The first liquid includes no water-repellent agent.

The second liquid supplied by the supply unit 61 will be described. For example, the second liquid is a rinse liquid. For example, the second liquid is deionized water (DIW).

Structures of the supply units 21, 31, 41, 51, and 61 will be described as an example.

The supply unit 21 includes an emission part 22, a pipe 23, and a valve 24. The emission part 22 emits the inert gas. The pipe 23 is connected to the emission part 22. The pipe 23 is also connected to a supply source 25. The supply source 25 stores the inert gas. The valve 24 is provided in the pipe 23. When the valve 24 is opened, the inert gas flows from the supply source 25 to the emission part 22 through the pipe 23. When the valve 24 is opened, the emission part 22 emits the inert gas. When the valve 24 is closed, the inert gas does not flow from the supply source 25 to the emission part 22 through the pipe 23. When the valve 24 is closed, the emission part 22 does not emit the inert gas.

Similarly, the supply units 31, 41, 51, and 61 respectively include emission parts 32, 42, 52, and 62; pipes 33, 43, 53, and 63; and valves 34, 44, 54, and 64. The emission part 32 emits the water-repellent agent. The emission part 42 emits the treatment gas. The emission part 52 emits the first liquid. The emission part 62 emits the second liquid. The pipes 33, 43, 53, and 63 are respectively connected to the emission parts 32, 42, 52, and 62. The pipes 33, 43, 53, and 63 are respectively connected to supply sources 35, 45, 55, and 65. The supply source 35 stores the water-repellent agent. The supply source 45 stores the treatment gas. The supply source 55 stores the first liquid. The supply source 65 stores the second liquid. The valves 34, 44, 54, and 64 are respectively provided in the pipes 33, 43, 53, and 63. The valves 34, 44, 54, and 64 control emission performed by the emission parts 32, 42, 52, and 62, respectively.

Each of the emission parts 22, 32, 42, 52, and 62 is installed inside the chamber 3. Each of the emission parts 22, 32, 42, and 52 is disposed at a position higher than the treatment tank 11. The emission part 22 is disposed on both sides of the substrate W positioned at the first position P1 in the direction Y. The emission parts 32, 42, and 52 are also disposed in a manner similar to that of the emission part 22. The emission part 62 is disposed inside the treatment tank 11.

The emission part 22 includes a tubular member. The tubular member extends in the direction X. The tubular member has a plurality of emission ports (not illustrated). The plurality of emission ports is arranged in the direction X. The emission part 22 emits the inert gas through the plurality of emission ports. The emission parts 32 and 42 have structures similar to the structure of the emission part 22.

The emission part 52 sprays the first liquid into the chamber 3. For example, the emission part 52 sprays at least any of droplets of the first liquid and mist of the first liquid into the chamber 3. For example, the emission part 52 sprays the first liquid at a wide angle. For example, the emission part 52 distributes the first liquid over a wide range.

For example, the emission part 52 includes a plurality of (for example, 20) shower head nozzles. The plurality of shower head nozzles is arranged in two rows in the direction X. Each of the shower head nozzles has a plurality of emission ports (not illustrated). Each of the shower head nozzles emits the first liquid through the plurality of emission ports. Each of the shower head nozzles emits the first liquid like a shower. Each of the shower head nozzles sprays many droplets of the first liquid.

The supply source 45 may also generate treatment gas in addition to storing the treatment gas. Although illustration is omitted, for example, the supply source 45 includes a tank and a heater. The tank communicates with and is connected to the pipe 43. The tank stores liquid of the organic solvent. The heater warms liquid of the organic solvent inside the tank. Inside the tank, liquid of the organic solvent is vaporized and becomes vapor of the organic solvent. That is, treatment gas is generated inside the tank.

The substrate treatment device 1 includes a decompression unit 81. The decompression unit 81 decompresses the inside of the chamber 3. Specifically, the decompression unit 81 discharges gas inside the chamber 3 to the outside of the chamber 3. Here, when the decompression unit 81 decompresses the inside of the chamber 3, the pressure of the gas inside the chamber 3 may continuously decrease or may not continuously decrease. When the decompression unit 81 decompresses the inside of the chamber 3, for example, the pressure of the gas inside the chamber 3 may be maintained within a predetermined negative pressure range.

A structure of the decompression unit 81 will be described as an example. The decompression unit 81 includes a pipe 82 and an exhaust pump 83. The pipe 82 and the exhaust pump 83 are provided outside the chamber 3. The pipe 82 communicates with and is connected to the chamber 3. The exhaust pump 83 is provided in the pipe 82. For example, the exhaust pump 83 is a vacuum pump. When the decompression unit 81 operates, the exhaust pump 83 discharges gas inside the chamber 3 to the outside of the chamber 3 via the pipe 82. When operation of the decompression unit 81 is stopped, the exhaust pump 83 does not discharge gas inside the chamber 3 to the outside of the chamber 3.

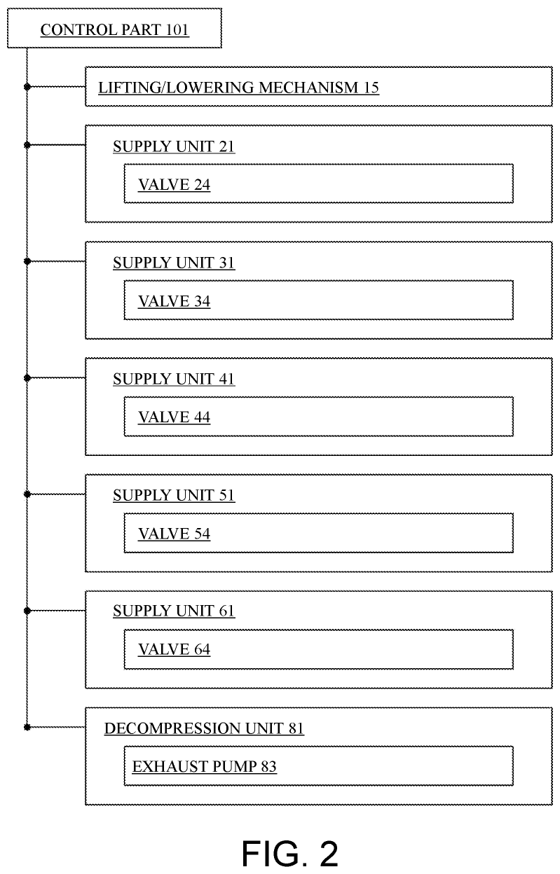

FIG. 2 is a control block diagram of the substrate treatment device 1. The substrate treatment device 1 includes a control part 101. The control part 101 controls each element of the substrate treatment device 1. Specifically, the control part 101 controls the lifting/lowering mechanism 15. The control part 101 controls the supply units 21, 31, 41, 51, and 61. The control part 101 controls the valves 24, 34, 44, 54, and 64. The control part 101 controls the decompression unit 81. The control part 101 controls the exhaust pump 83.

The control part 101 is realized by a central processing unit (CPU) executing various kinds of processing, a random-access memory (RAM) serving as a work domain for arithmetic processing, a storage medium such as a hard disk, and the like. The control part 101 has various kinds of information which has been stored in the storage medium in advance. For example, information of the control part 101 is processing information for controlling the substrate treatment device 1. Processing information is also referred to as a processing recipe.

### 1-2. Examples of Operation of Substrate Treatment Device

A device (not illustrated) different from the substrate treatment device 1 performs wet etching treatment with respect to the substrate W. For example, wet etching treatment is treatment of supplying an etching liquid to the substrate W. Thereafter, the substrate W is conveyed to the substrate treatment device 1. The chamber 3 is opened. A plurality of substrates W enters the inside of the chamber 3. The holding part 13 receives the plurality of substrates W. In a state in which the chamber 3 accommodates the substrates W, the chamber 3 is closed.

In a state in which the chamber 3 is closed, the substrate treatment device 1 executes a substrate treatment method with respect to the substrates W. The substrate treatment method is a method for simultaneously treating a plurality of substrates W accommodated inside the chamber 3. A specific substrate treatment method will be described below as an example.

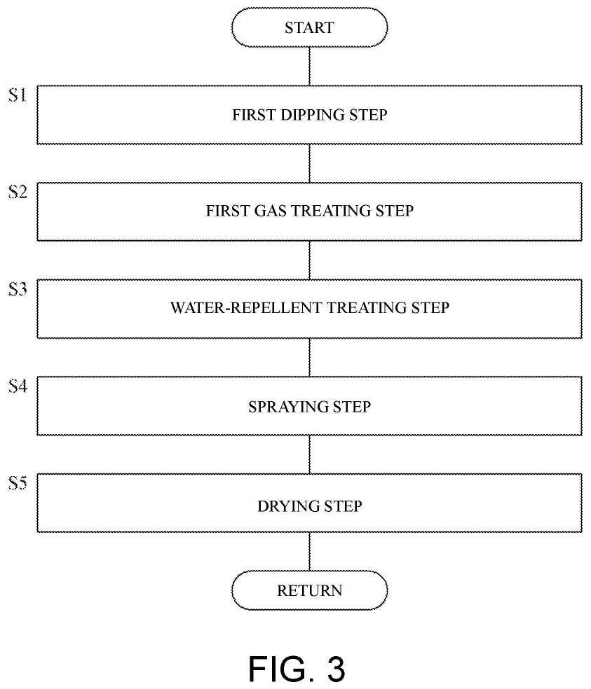

FIG. 3 is a flowchart showing a procedure of the substrate treatment method of the first embodiment. The substrate treatment method includes a first dipping step, a first gas treating step, a water-repellency treatment step, a spraying step, and a drying step. The first dipping step, the first gas treating step, the water-repellency treatment step, the spraying step, and the drying step are executed in this order.

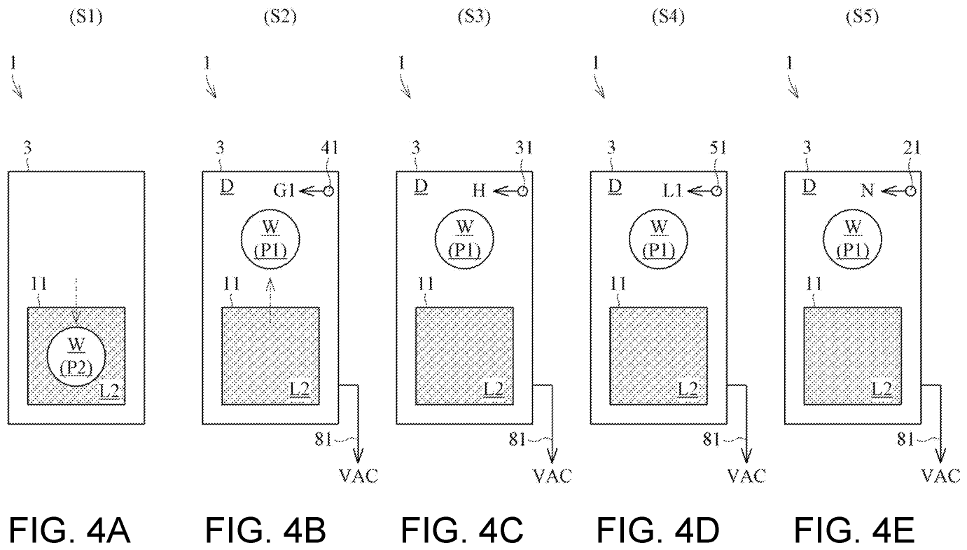

FIG. 4A is a view schematically illustrating the substrate treatment device 1 in the first dipping step. FIG. 4B is a view schematically illustrating the substrate treatment device 1 in the first gas treating step. FIG. 4C is a view schematically illustrating the substrate treatment device 1 in the water-repellency treatment step. FIG. 4D is a view schematically illustrating the substrate treatment device 1 in the spraying step. FIG. 4E is a view schematically illustrating the substrate treatment device 1 in the drying step. In each of FIGS. 4A to 4E, the substrate treatment device 1 is simply illustrated. For example, in each of FIGS. 4A to 4E, illustration of the holding part 13 and the lifting/lowering mechanism 15 is omitted. In the following description, it is considered that each element of the substrate treatment device 1 operates in response to control of the control part 101.

Step S1: First Dipping Step

Refer to FIG. 4A. The treatment tank 11 stores a second liquid L2 supplied from the supply unit 61. The lifting/lowering mechanism 15 moves the substrate W to the second position P2. The substrate W is dipped into the second liquid L2 inside the treatment tank 11.

Step S2: First Gas Treating Step (First Gas Treatment)

Refer to FIG. 4B. The supply unit 41 supplies the treatment gas to the inside of the chamber 3. In this specification, the treatment gas supplied to the chamber 3 in the first gas treating step will be suitably referred to as “a first gas G1”. The decompression unit 81 operates. That is, the decompression unit 81 decompresses the inside of the chamber 3. “VAC” in FIG. 4B indicates that the decompression unit 81 is in operation. The inside of the chamber 3 shifts to a decompressed state D. When the inside of the chamber 3 is in the decompressed state D, the pressure of the gas inside the chamber 3 becomes a negative pressure. An atmosphere of the first gas G1 is formed inside the chamber 3. The lifting/lowering mechanism 15 moves the substrate W from the second position P2 to the first position P1. The substrate W is picked up from the second liquid L2 inside the treatment tank 11. In the state D in which the inside of the chamber 3 is decompressed, the supply unit 41 supplies the first gas G1 to the substrate W inside the chamber 3. The substrate W is exposed to the first gas G1. The gas of the organic solvent included in the first gas G1 is dew-condensed on the surface of the substrate W. That is, the gas of the organic solvent included in the first gas G1 changes to liquid of the organic solvent on the surface of the substrate W. The liquid of the organic solvent derived from the first gas G1 adheres to a part on the substrate W. The organic solvent derived from the first gas G1 removes the second liquid L2 on the substrate W. Since the inside of the chamber 3 is in the decompressed state D, the second liquid L2 is quickly replaced by the organic solvent on the substrate W. The liquid of the organic solvent derived from the first gas G1 covers the surface of the substrate W.

Step S3: Water-Repellency Treatment Step (Water-Repellency Treatment)

Refer to FIG. 4C. The substrate W is positioned at the first position P1. The decompression unit 81 is in operation. The inside of the chamber 3 is maintained in the decompressed state D. The supply unit 41 stops supplying of the first gas G1. The supply unit 31 supplies a water-repellent agent H to the substrate W inside the chamber 3. The water-repellent agent H adheres to the substrate W. When the supply unit 31 supplies gas of the water-repellent agent H, the gas of the water-repellent agent H is dew-condensed on the surface of the substrate W and changes to liquid of the water-repellent agent H on the surface of the substrate W. When the supply unit 31 supplies liquid of the water-repellent agent H, the liquid of the water-repellent agent H adheres to the surface of the substrate W. Since the inside of the chamber 3 is in the decompressed state D, the liquid of the organic solvent is quickly replaced by the water-repellent agent H on the substrate W. The water-repellent agent H covers the surface of the substrate W. The water-repellent agent H causes the substrate W to be water repellent.

A portion of the water-repellent agent H on the substrate W changes to a water-repellent film. The water-repellent film is formed on the surface of the substrate W. Other portions of the water-repellent agent H on the substrate W become an unreacted portion of the water-repellent agent H. The unreacted portion of the water-repellent agent H does not react and remains on the substrate W as it is. The unreacted portion of the water-repellent agent H is also referred to as a residue of the water-repellent agent H or a surplus of the water-repellent agent H. Moreover, another portion of the water-repellent agent H on the substrate W may change to particles. The particles are also referred to as foreign matters. For example, particles derived from the water-repellent agent H are generated when the water-repellent agent H comes into contact with the organic solvent. For example, particles derived from the water-repellent agent H are generated when the water-repellent agent H comes into contact with the substrate W. Moreover, the unreacted portion of the water-repellent agent H may become particles derived from the water-repellent agent H.

Step S4: Spraying Step (Spraying Treatment)

Refer to FIG. 4D. The substrate W is positioned at the first position P1. The decompression unit 81 is in operation. The inside of the chamber 3 is maintained in the decompressed state D. The supply unit 31 stops supplying of the water-repellent agent H. The supply unit 51 sprays a first liquid L1 over the substrate W inside the chamber 3. For example, the supply unit 51 sprays at least any of droplets of the first liquid L1 and mist of the first liquid L1. For example, the supply unit 51 sprays the first liquid L1 through the shower head nozzles. The first liquid L1 adheres to the substrate W. The first liquid L1 removes the unreacted water-repellent agent H on the substrate W. The first liquid L1 also removes the particles derived from the water-repellent agent H on the substrate W. Since the inside of the chamber 3 is in the decompressed state D, the water-repellent agent H is quickly replaced by the first liquid L1 on the substrate. Since the inside of the chamber 3 is in the decompressed state D, the particles derived from the water-repellent agent H are also quickly removed from the substrate W. The first liquid L1 covers the surface of the substrate W.

In the spraying step, the lifting/lowering mechanism 15 may cause the substrate W to stand still at the first position P1. Alternatively, in the spraying step, the lifting/lowering mechanism 15 may vertically move the substrate W. For example, the lifting/lowering mechanism 15 may vertically move the substrate W near the first position P1. For example, the lifting/lowering mechanism 15 may vertically move the substrate W in the vertical direction Z. Alternatively, the lifting/lowering mechanism 15 may further include a mechanism (not illustrated) for swinging the substrate W. The lifting/lowering mechanism 15 may swing the substrate W by means of the mechanism. When the substrate W is vertically moved or swung, the entire substrate W favorably receives the first liquid L1. When the substrate W is vertically moved or swung, the first liquid L1 adheres more uniformly to the entire surface of the substrate W.

Step S5: Drying Step

The substrate W is positioned at the first position P1. The decompression unit 81 is in operation. The inside of the chamber 3 is maintained in the decompressed state D. The supply unit 51 stops spraying of the first liquid L1. The supply unit 21 supplies inert gas N to the substrate W. The substrate W is exposed to the inert gas N. The inert gas N removes the first liquid L1 on the substrate W. The substrate W dries upon removal of the first liquid L1 from the substrate W.

Here, the substrate W is caused to be water repellent. For this reason, when the first liquid L1 is removed from the substrate W, a small force is applied to the substrate W by the first liquid. Since the inside of the chamber 3 is in the decompressed state D, the first liquid L1 is removed from the substrate W in a short period of time. For this reason, when the first liquid L1 is removed from the substrate W, a smaller force is applied to the substrate W by the first liquid. Therefore, when the first liquid L1 is removed from the substrate W, the substrate W is favorably protected. When the first liquid L1 is removed from the substrate W, the pattern on the substrate W is favorably protected. For example, when the first liquid L1 is removed from the substrate W, collapse of the pattern is favorably prevented.

Although illustration is omitted, after the drying step, the inside of the chamber 3 is pressurized. For example, the supply unit 61 supplies the inert gas N, and the decompression unit 81 stops operation. Accordingly, the pressure inside the chamber 3 rises. The inside of the chamber 3 shifts from the decompressed state D to an atmospheric pressure state.

The atmospheric pressure state will be described. The inside of the chamber 3 being in an atmospheric pressure state denotes that the pressure of the gas inside the chamber 3 is an atmospheric pressure. The atmospheric pressure indicates a range stipulated by two different values instead of one particular value. The atmospheric pressure is higher than the pressure of the gas inside the chamber 3 when the inside of the chamber 3 is in the decompressed state D. The atmospheric pressure is close to the pressure of gas outside the chamber 3. For example, the atmospheric pressure is practically equivalent to the pressure of gas outside the chamber 3. For example, the atmospheric pressure includes a standard atmospheric pressure (1 atm, 101,325 Pa).

After the chamber 3 has shifted to the atmospheric pressure state, the chamber 3 is open. Further, the substrate W inside the chamber 3 is carried out to the outside of the chamber 3.

### 1-3. Effects of First Embodiment

The substrate treatment method includes the first gas treating step, the water-repellency treatment step, and the spraying step. In the first gas treating step, the inside of the chamber 3 is in the decompressed state D, and the first gas G1 is supplied to the substrate W inside the chamber 3. The first gas G1 includes gas of the organic solvent. The water-repellency treatment step is executed after the first gas treating step. In the water-repellency treatment step, the inside of the chamber 3 is in the decompressed state D, and the water-repellent agent H is supplied to the substrate W inside the chamber 3. The spraying step is executed after the water-repellency treatment. In the spraying step, the inside of the chamber 3 is in the decompressed state D, and the first liquid L1 is sprayed over the substrate W inside the chamber 3. Even in the state D in which the inside of the chamber 3 is decompressed, it is easy to spray the first liquid L1 over the substrate W. The first liquid L1 includes liquid of the organic solvent. Since the first liquid is a liquid, the first liquid L1 has a relatively high density. For example, the density of the first liquid L1 is higher than the density of the first gas G1. For this reason, the substrate W receives a relatively large quantity of the first liquid L1 in the spraying step. For example, the substrate W receives a relatively large mass of the first liquid L1 in the spraying step. Thus, in the spraying step, particles on the substrate W are favorably removed. Therefore, the quantity of particles on the substrate W is favorably reduced. As a result, the cleanness of the substrate W is favorably improved. The treatment quality of the substrate W is favorably improved.

In the water-repellency treatment step, particles derived from the water-repellent agent H may be generated on the substrate W. Even in such a case, in the spraying step, the first liquid L1 also favorably removes particles derived from the water-repellent agent H on the substrate W.

As above, in the substrate treatment method of the first embodiment, particles on the substrate W can be favorably reduced.

In the spraying step, at least any of droplets of the first liquid L1 and mist of the first liquid L1 is sprayed. For this reason, in the spraying step, the first liquid L1 is efficiently supplied to the substrate W. For example, while the consumption quantity of the first liquid L1 is restricted, the first liquid L1 can be adhered to the entire substrate W.

In the spraying step, the first liquid L1 is sprayed through the shower head nozzles. For this reason, in the spraying step, the first liquid L1 is efficiently supplied to the substrate W. For example, while the consumption quantity of the first liquid L1 is restricted, the first liquid L1 can be adhered to the entire substrate W.

The substrate treatment method includes the first dipping step. The first dipping step is executed before the first gas treating step. In the first dipping step, the substrate W is dipped into the second liquid L2 stored in the treatment tank 11. The treatment tank 11 is installed inside the chamber 3. After the first dipping step, the first gas treating step, the water-repellency treatment step, and the spraying step are executed. In the first gas treating step, the water-repellency treatment step, and the spraying step, the inside of the chamber 3 is in the decompressed state D. For this reason, the inside of the chamber 3 is in the decompressed state D until the spraying step after the first dipping step. When the inside of the chamber 3 is in the decompressed state D, it is difficult to discharge the second liquid L2 to the outside of the chamber 3. Thus, when the inside of the chamber 3 is in the decompressed state D, in the treatment tank 11 it is difficult for the second liquid L2 to be replaced by the first liquid L1. Therefore, it is difficult to use the treatment tank 11 in order to supply the first liquid L1 to the substrate W until the spraying step after the first dipping step. In the spraying step, the first liquid L1 is sprayed over the substrate W without using the treatment tank 11. For this reason, the first dipping step does not limit execution of the spraying step. Even when the substrate treatment method includes the first dipping step, it is easy to execute the spraying step. Instead, when the substrate treatment method includes the first dipping step, the spraying step is extremely useful.

In the first gas treating step, the water-repellency treatment step, and the spraying step, the substrate W is positioned above the treatment tank 11. Specifically, in the first gas treating step, the water-repellency treatment step, and the spraying step, the substrate W is positioned at the first position P1. For this reason, in the first gas treating step, the substrate W favorably receives the first gas G1. In the water-repellency treatment step, the substrate W favorably receives the water-repellent agent H. In the spraying step, the substrate W favorably receives the first liquid L1.

The substrate treatment device 1 includes the chamber 3, the supply units 31, 41, and 51, the decompression unit 81, and the control part 101. The chamber 3 accommodates a plurality of substrates W. The supply unit 31 supplies the water-repellent agent H to the substrate W inside the chamber 3. The supply unit 41 supplies the first gas G1 to the substrate W inside the chamber 3. The supply unit 51 supplies the first liquid L1 to the substrate W inside the chamber 3. The decompression unit 81 decompresses the inside of the chamber 3. The control part 101 executes the first gas treatment, the water-repellency treatment, and the spraying treatment by controlling the supply units 31, 41, and 51 and the decompression unit 81. In the first gas treatment, the decompression unit 81 decompresses the inside of the chamber 3, and the supply unit 41 supplies the first gas G1 to the substrate W. In the water-repellency treatment, the decompression unit 81 decompresses the inside of the chamber 3, and the supply unit 31 supplies the water-repellent agent H to the substrate W. In the spraying treatment, the decompression unit 81 decompresses the inside of the chamber 3, and the supply unit 51 sprays the first liquid L1 over the substrate W. Even when the decompression unit 81 is decompressing the inside of the chamber 3, the supply unit 51 can favorably spray the first liquid L1 over the substrate W. In the spraying treatment, the first liquid L1 favorably removes particles on the substrate W. Therefore, the quantity of particles on the substrate W is favorably reduced. As a result, the cleanness of the substrate W is favorably improved. The treatment quality of the substrate W is favorably improved.

In the water-repellency treatment, particles derived from the water-repellent agent H may be generated on the substrate W. Even in such a case, in the spraying treatment, the first liquid L1 also favorably removes particles derived from the water-repellent agent H on the substrate W.

As above, in the substrate treatment device 1 of the first embodiment, particles on the substrate W can be favorably reduced.

### 2. Second Embodiment

A second embodiment will be described with reference to the drawings. The same reference signs are applied to the same constituents as the first embodiment, and therefore detailed description thereof will be omitted.

### 2-1. Overview of Substrate Treatment Device

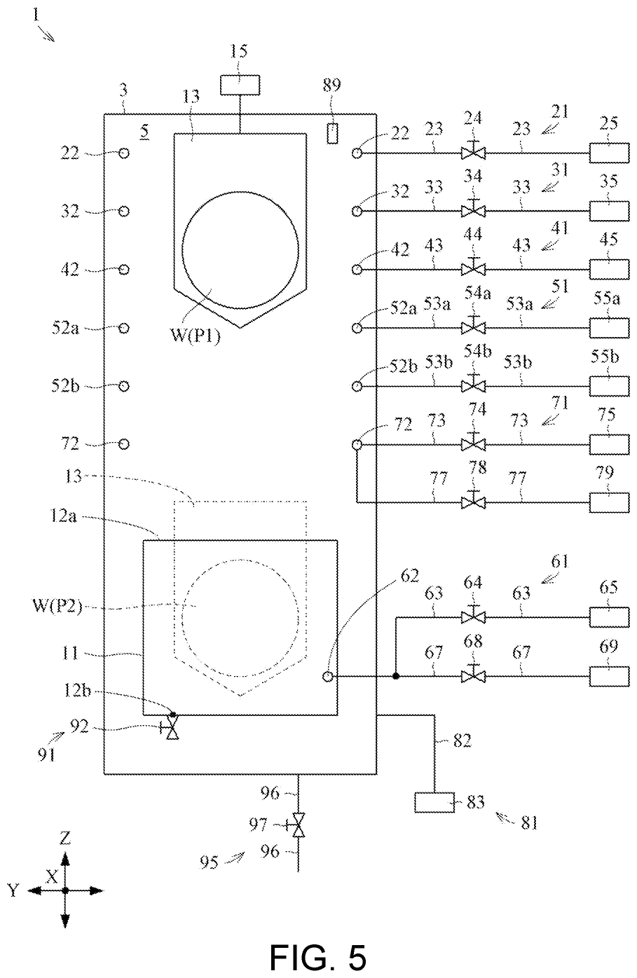

FIG. 5 is a front view illustrating the inside of the substrate treatment device 1 of the second embodiment. The supply unit 51 supplies two kinds of first liquids L1. Hereinafter, the first liquid L1 of one kind will be referred to as “a diluted first liquid L1a”. The first liquid of the other kind will be referred to as “an undiluted first liquid Llb”.

The diluted first liquid L1a is a diluted organic solvent. The diluted first liquid L1a is an organic solvent diluted with deionized water. The diluted first liquid L1a is a mixed liquid of deionized water and an organic solvent. For example, the organic solvent of the diluted first liquid L1a is isopropyl alcohol (IPA).

The undiluted first liquid L1b is an undiluted organic solvent. The undiluted first liquid L1b practically consists of only liquid of the organic solvent. The undiluted first liquid L1b is an undiluted solution of an organic solvent. The undiluted first liquid L1b practically includes no water. For example, the organic solvent of the undiluted first liquid L1b is isopropyl alcohol (IPA).

A structure of the supply unit 51 will be described as an example. The supply unit 51 includes emission parts 52a and 52b. Each of the emission parts 52a and 52b is disposed inside the chamber 3. Each of the emission parts 52a and 52b is disposed at a position higher than the treatment tank 11. The emission part 52a is disposed on both sides of the substrate W positioned at the first position P1 in the direction Y. The emission part 52a has a structure similar to the structure of the emission part 52 according to the first embodiment. The emission part 52a sprays the diluted first liquid L1a into the chamber 3. Similarly, the emission part 52b is disposed on both sides of the substrate W positioned at the first position P1 in the direction Y. The emission part 52b sprays the undiluted first liquid L1b into the chamber 3. The emission part 52b has a structure similar to the structure of the emission part 52 according to the first embodiment.

The supply unit 51 includes a pipe 53a and a valve 54a. The pipe 53a is connected to the emission part 52a. The pipe 53a is also connected to a supply source 55a. The supply source 55a stores the diluted first liquid L1a. The valve 54a is provided in the pipe 53a. The valve 54a controls spraying of the diluted first liquid L1a performed by the emission part 52a. Similarly, the supply unit 51 includes a pipe 53b and a valve 54b. The pipe 53b is connected to the emission part 52b. The pipe 53b is also connected to a supply source 55b. The supply source 55b stores the undiluted first liquid L1b. The valve 54b is provided in the pipe 53b. The valve 54b controls spraying of the undiluted first liquid L1b performed by the emission part 52b.

The supply unit 61 supplies a third liquid L3 to the treatment tank 11 in addition to the second liquid L2. The third liquid L3 is a diluted organic solvent. For example, the third liquid L3 is an organic solvent diluted with deionized water. For example, the third liquid L3 is a mixed liquid of deionized water and an organic solvent.

A structure of the supply unit 61 will be described as an example. The supply unit 61 includes a pipe 67 and a valve 68. The pipe 67 is connected to the emission part 62. The pipe 67 is also connected to a supply source 69. The supply source 69 stores the third liquid L3. The valve 68 is provided in the pipe 67. The valve 68 controls emission of the third liquid L3 performed by the emission part 62.

The substrate treatment device 1 includes a supply unit 71. The supply unit 71 supplies mixed gas to the chamber 3. When the substrate W is positioned at the first position P1, the supply unit 71 supplies the mixed gas to the substrate W.

The mixed gas will be described. The mixed gas includes an organic solvent and inert gas. The mixed gas is a mixture of an organic solvent and inert gas. The mixed gas includes at least any of gas of the organic solvent and liquid of the organic solvent. That is, the organic solvent of the mixed gas is in at least any of a gas phase and a liquid phase. For example, the gas of the organic solvent in the mixed gas is vapor of the organic solvent. For example, the liquid of the organic solvent in the mixed gas is at least any of droplets of the organic solvent or mist of the organic solvent. For example, the organic solvent of the mixed gas is isopropyl alcohol (IPA). For example, the inert gas of the mixed gas is nitrogen gas.

A structure of the supply unit 71 will be described as an example. The supply unit 71 has an emission part 72. The emission part 72 is installed inside the chamber 3. The emission part 72 is disposed at a position higher than the treatment tank 11. The emission part 72 is disposed on both sides of the substrate W positioned at the first position P1 in the direction Y. The emission part 72 emits the mixed gas into the chamber 3. The emission part 72 includes a plurality of (for example, 20) two-fluid nozzles. The plurality of two-fluid nozzles is arranged in two rows in the direction X. Each of the two-fluid nozzles generates mixed gas by mixing an organic solvent and inert gas. For example, each of the two-fluid nozzles generates at least any of droplets of the organic solvent and mist of the organic solvent. Each of the two-fluid nozzles has one emission port (not illustrated). Each of the two-fluid nozzles emits the mixed gas through the emission port. Each of the two-fluid nozzles emits both the organic solvent and the inert gas through the emission port. Each of the two-fluid nozzles simultaneously emits both the organic solvent and the inert gas through the emission port. Each of the two-fluid nozzles does not individually emit the organic solvent and the inert gas. Each of the two-fluid nozzles injects at least any of droplets of the organic solvent and mist of the organic solvent together with the inert gas.

The supply unit 71 includes pipes 73 and 77 and valves 74 and 78. Each of the pipes 73 and 77 is connected to the emission part 72. The pipe 73 is also connected to a supply source 75. The supply source 75 stores an organic solvent. The valve 74 is provided in the pipe 73. The valve 74 controls supplying of the organic solvent to the emission part 72. The pipe 77 is also connected to a supply source 79. The supply source 79 stores the inert gas. The valve 78 is provided in the pipe 77. The valve 78 controls supplying of the inert gas to the emission part 72. When the valves 74 and 78 are simultaneously opened, the emission part 72 emits the mixed gas.

The substrate treatment device 1 has a pressure sensor 89. The pressure sensor 89 is installed inside the chamber 3. The pressure sensor 89 detects the pressure of the gas inside the chamber 3.

The treatment tank 11 has an opening 12a and a discharge port 12b. The opening 12a is disposed in an upper part of the treatment tank 11. The opening 12a is sufficiently large. When the substrate W moves between the first position P1 and the second position P2, the substrate W passes through the opening 12a. The discharge port 12b is disposed in a bottom part of the treatment tank 11.

The substrate treatment device 1 includes a dumping unit 91. The dumping unit 91 releases the treatment liquid inside the treatment tank 11. The chamber 3 receives the treatment liquid released from the treatment tank 11. The treatment liquid released from the treatment tank 11 is accumulated in a bottom part of the chamber 3. The dumping unit 91 includes a dumping valve 92. The dumping valve 92 is installed inside the chamber 3. The dumping valve 92 is attached to the bottom part of the treatment tank 11. The dumping valve 92 communicates with and is connected to the discharge port 12b. When the dumping valve 92 is opened, the dumping unit 91 allows the treatment liquid to flow down from the inside of the treatment tank 11 to the outside of the treatment tank 11 through the dumping valve 92. When the dumping valve 92 is closed, the dumping unit 91 allows the treatment tank 11 to store the treatment liquid.

The substrate treatment device 1 includes a liquid discharge unit 95. The liquid discharge unit 95 discharges the treatment liquid inside the chamber 3 to the outside of the chamber 3. The liquid discharge unit 95 includes a pipe 96 and a drain valve 97. The pipe 96 is provided outside the chamber 3. The pipe 96 communicates with and is connected to the chamber 3. The pipe 96 has a first end and a second end. The first end of the pipe 96 communicates with and is connected to the chamber 3. The first end of the pipe 96 is connected to the bottom part of the chamber 3. The pipe 96 extends downward from the chamber 3. The second end of the pipe 96 is open to the atmospheric air outside the chamber 3. The drain valve 97 is provided in the pipe 96. The drain valve 97 opens and closes the pipe 96. When the drain valve 97 is opened, the pipe 96 is open to the outside of the chamber 3. When the drain valve 97 is opened, the inside of the chamber 3 is open to the outside of the chamber 3 through the pipe 96. When the drain valve 97 is opened, the liquid discharge unit 95 allows the treatment liquid inside the chamber 3 to flow out of the chamber 3 through the pipe 96. When the drain valve 97 is closed, the inside of the chamber 3 is isolated from the outside of the chamber 3. When the drain valve 97 is closed, the liquid discharge unit 95 allows the inside of the chamber 3 to shift to the decompressed state D.

The pipe 96 is an example of a liquid discharge tube according to the disclosure.

Although illustration is omitted, the control part 101 controls the valve 68. The control part 101 controls the supply unit 71. The control part 101 controls the valves 74 and 78. The control part 101 acquires detection results of the pressure sensor 89. The control part 101 controls the dumping unit 91 and the liquid discharge unit 95. The control part 101 controls the dumping valve 92 and the drain valve 97.

### 2-2. Examples of Operation of Substrate Treatment Device

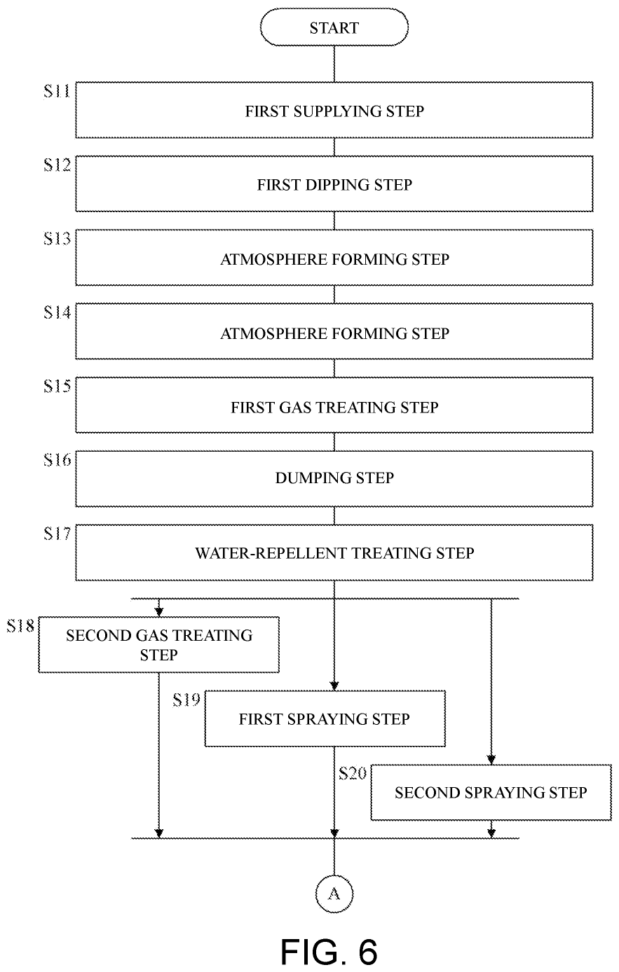

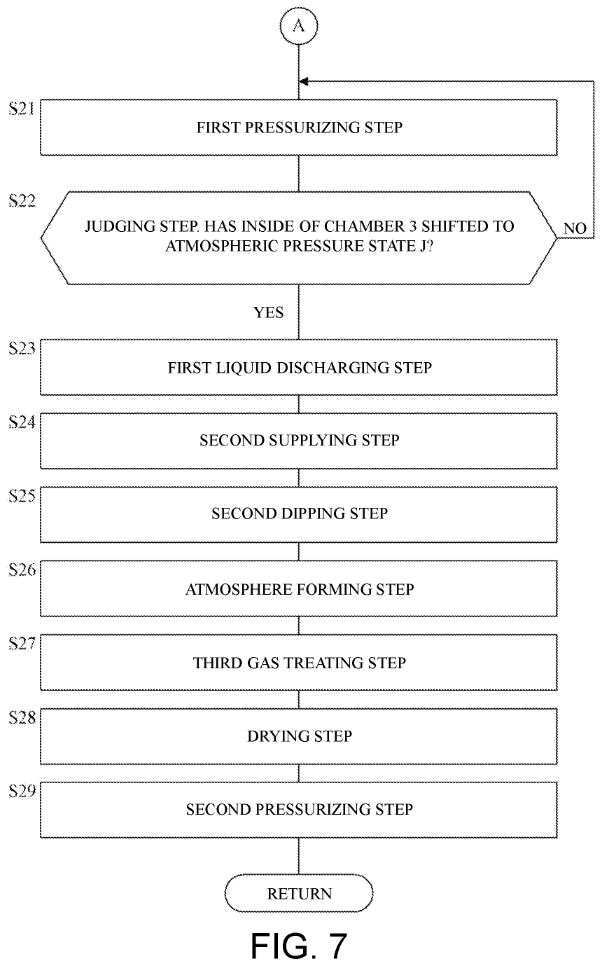

FIGS. 6 and 7 are flowcharts each of which shows a procedure of the substrate treatment method of the second embodiment. The substrate treatment method includes Steps S11 to S29. Steps S11 to S17 are executed in this order. Steps S18 to S20 are executed after Step S17 and before Step S21. Steps S21 to S29 are executed in this order.

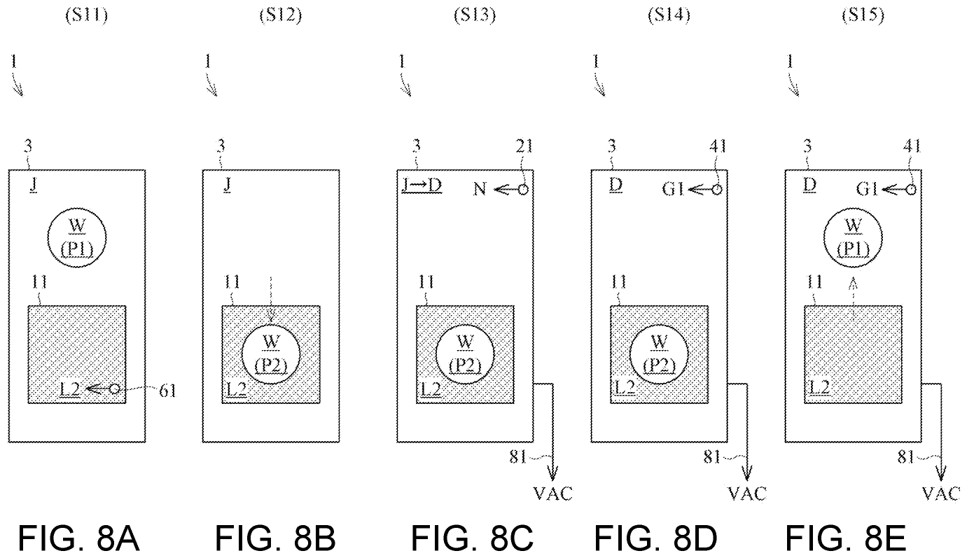

FIGS. 8A to 8E, 9A to 9E, 10A to 10E, and 11A to 11C are views each of which schematically illustrates the substrate treatment device 1 in Steps S11 to S21 and S23 to S29. Each of FIGS. 8A to 8E and the like simply illustrates the substrate treatment device 1.

Step S11: First Supplying Step

Refer to FIG. 8A. The substrate W is positioned at the first position P1. The inside of the chamber 3 is in an atmospheric pressure state J. The supply unit 61 supplies the second liquid L2 to the treatment tank 11. A dumping valve 92 is closed. The treatment tank 11 stores the second liquid L2. Thereafter, the supply unit 61 stops supplying of the second liquid L2.

Step S12: First Dipping Step

Refer to FIG. 8B. The inside of the chamber 3 is in the atmospheric pressure state J. The lifting/lowering mechanism 15 moves the substrate W from the first position P1 to the second position P2. The substrate W is dipped into the second liquid L2 inside the treatment tank 11.

Step S13: Atmosphere Forming Step

Refer to FIG. 8C. The substrate W is positioned at the second position P2 and is dipped into the second liquid L2 inside the treatment tank 11. The supply unit 21 supplies the inert gas N to the inside of the chamber 3. The decompression unit 81 starts operation. The drain valve 97 is closed. The inside of the chamber 3 shifts from the atmospheric pressure state J to the decompressed state D. An atmosphere of the inert gas N is formed inside the chamber 3.

Step S14: Atmosphere Forming Step

Refer to FIG. 8D. The substrate W is positioned at the second position P2 and is dipped into the second liquid L2 inside the treatment tank 11. The decompression unit 81 is in operation. The inside of the chamber 3 is maintained in the decompressed state D. The supply unit 21 stops supplying of the inert gas N. The supply unit 41 supplies the first gas G1 to the inside of the chamber 3. An atmosphere of the first gas G1 is formed inside the chamber 3.

Step S15: First Gas Treating Step (First Gas Treatment)

Refer to FIG. 8E. The decompression unit 81 is in operation. The inside of the chamber 3 is maintained in the decompressed state D. The supply unit 41 supplies the first gas G1 to the inside of the chamber 3. The lifting/lowering mechanism 15 moves the substrate W from the second position P2 to the first position P1. The substrate W is picked up from the second liquid L2 inside the treatment tank 11. The substrate W is exposed to the first gas G1. The gas of the organic solvent included in the first gas G1 changes to liquid of the organic solvent on the surface of the substrate W. The organic solvent derived from the first gas G1 removes the second liquid L2 on the substrate W. The liquid of the organic solvent derived from the first gas G1 covers the surface of the substrate W.

Step S16: Dumping Step

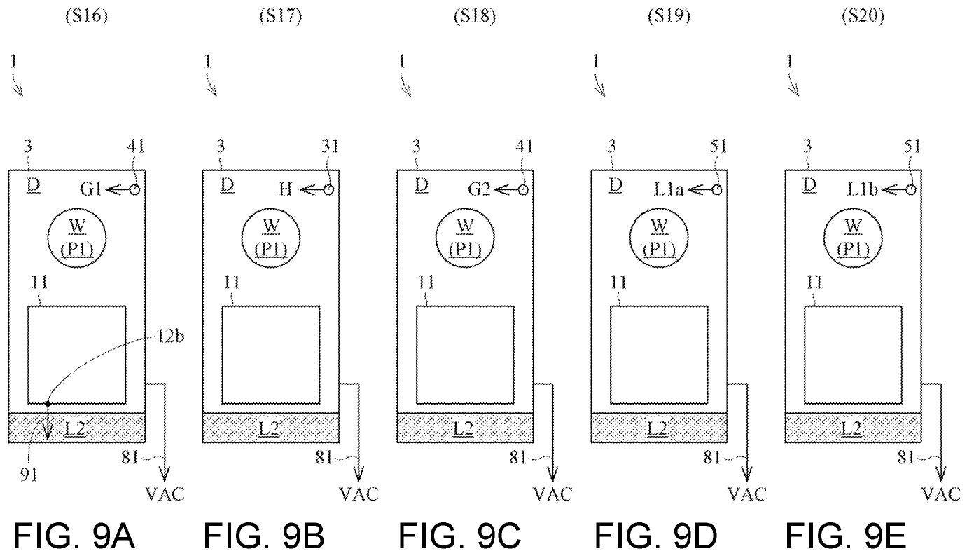

Refer to FIG. 9A. The substrate W is positioned at the first position P1. The supply unit 41 supplies the first gas G1 to the substrate W inside the chamber 3. The decompression unit 81 is in operation. The inside of the chamber 3 is maintained in the decompressed state D. The dumping valve 92 is opened. The dumping unit 91 releases the second liquid L2 from the treatment tank 11. The drain valve 97 is closed. The second liquid L2 is accumulated in the bottom part of the chamber 3.

Step S17: Water-Repellency Treatment Step (Water-Repellency Treatment)

Refer to FIG. 9B. The substrate W is positioned at the first position P1. The decompression unit 81 is in operation. The inside of the chamber 3 is maintained in the decompressed state D. The supply unit 41 stops supplying of the first gas G1. The supply unit 31 supplies the water-repellent agent H to the substrate W inside the chamber 3. The water-repellent agent H adheres to the substrate W. On the substrate W, the organic solvent derived from the first gas G1 is replaced by the water-repellent agent H. The water-repellent agent H covers the surface of the substrate W. The water-repellent agent H causes the substrate W to be water repellent. A portion of the water-repellent agent H on the substrate W changes to a water-repellent film. Other portions of the water-repellent agent H on the substrate W become an unreacted portion of the water-repellent agent H. Moreover, another portion of the water-repellent agent H on the substrate W may change to particles.

Thereafter, the supply unit 31 stops supplying of the water-repellent agent H.

Step S18: Second Gas Treating Step

Refer to FIG. 9C. The substrate W is positioned at the first position P1. The decompression unit 81 is in operation. The inside of the chamber 3 is maintained in the decompressed state D. The supply unit 41 supplies the treatment gas to the substrate W inside the chamber 3. In this specification, the treatment gas supplied to the chamber 3 in a second gas treating step will be suitably referred to as “a second gas G2”. The gas of the organic solvent included in the second gas G2 changes to liquid of the organic solvent on the surface of the substrate W. The organic solvent derived from the second gas G2 removes the unreacted water-repellent agent H on the substrate W. The organic solvent derived from the second gas G2 also removes particles derived from the water-repellent agent H on the substrate W. The liquid of the organic solvent derived from the second gas G2 covers the surface of the substrate W. Thereafter, the supply unit 41 stops supplying of the second gas G2.

Step S19: First Spraying Step (Spraying Treatment)

Refer to FIG. 9D. The substrate W is positioned at the first position P1. The decompression unit 81 is in operation. The inside of the chamber 3 is maintained in the decompressed state D. The supply unit 51 sprays the diluted first liquid L1a over the substrate W inside the chamber 3. The diluted first liquid L1a adheres to the substrate W. The diluted first liquid L1a removes the unreacted water-repellent agent H on the substrate W. The diluted first liquid L1a also removes particles derived from the water-repellent agent H on the substrate W. The diluted first liquid L1a covers the surface of the substrate W.

In a first spraying step, the lifting/lowering mechanism 15 may cause the substrate W to stand still at the first position P1. Alternatively, in the first spraying step, the lifting/lowering mechanism 15 may vertically move the substrate W. For example, the lifting/lowering mechanism 15 may vertically move the substrate W near the first position P1. For example, the lifting/lowering mechanism 15 may vertically move the substrate W in the vertical direction Z. Alternatively, the lifting/lowering mechanism 15 may further include a mechanism (not illustrated) for swinging the substrate W. The lifting/lowering mechanism 15 may swing the substrate W by means of the mechanism. When the substrate W is vertically moved or swung, the entire substrate W favorably receives the diluted first liquid L1a. When the substrate W is vertically moved or swung, the diluted first liquid L1a adheres more uniformly to the entire surface of the substrate W.

Thereafter, the supply unit 51 stops spraying of the diluted first liquid L1a.

Step S20: Second Spraying Step (Spraying Treatment)

Refer to FIG. 9E. The substrate W is positioned at the first position P1. The decompression unit 81 is in operation. The inside of the chamber 3 is maintained in the decompressed state D. The supply unit 51 sprays the undiluted first liquid L1b over the substrate W inside the chamber 3. The undiluted first liquid L1b adheres to the substrate W. The undiluted first liquid L1b removes the unreacted water-repellent agent H on the substrate W. The undiluted first liquid L1b also removes particles derived from the water-repellent agent H on the substrate W. The undiluted first liquid L1b covers the surface of the substrate W.

In a second spraying step, the lifting/lowering mechanism 15 may cause the substrate W to stand still at the first position P1. Alternatively, in the second spraying step, the lifting/lowering mechanism 15 may vertically move the substrate W. For example, the lifting/lowering mechanism 15 may vertically move the substrate W near the first position P1. For example, the lifting/lowering mechanism 15 may vertically move the substrate W in the vertical direction Z. Alternatively, the lifting/lowering mechanism 15 may further include a mechanism (not illustrated) for swinging the substrate W. The lifting/lowering mechanism 15 may swing the substrate W by means of the mechanism. When the substrate W is vertically moved or swung, the entire substrate W favorably receives the undiluted first liquid L1b. When the substrate W is vertically moved or swung, the undiluted first liquid L1b adheres more uniformly to the entire surface of the substrate W.

Thereafter, the supply unit 51 stops spraying of the undiluted first liquid L1b.

Here, the second gas treating step, the first spraying step, and the second spraying step may be executed in an arbitrary order. For example, the first spraying step may be executed before the second gas treating step. For example, the first spraying step may be executed after the second gas treating step. For example, the first spraying step may be simultaneously executed with the second gas treating step. Similarly, for example, the second spraying step may be executed at least any of before and after the first spraying step. For example, the second spraying step may be simultaneously executed with the first spraying step. For example, the second gas treating step may be executed at least any of before and after the second spraying step. For example, the second gas treating step may be simultaneously executed with the second spraying step.

Here, the first spraying step and the second spraying step will be generically referred to as a spraying step. The quantity of the diluted first liquid L1a supplied by the supply unit 51 in the first spraying step will be referred to as a quantity M1a. The quantity of the undiluted first liquid L1b supplied by the supply unit 51 in the second spraying step will be referred to as a quantity M1b. The total quantity of the quantity M1a and the quantity M1b will be referred to as a quantity M1. The quantity M1 corresponds to the quantity of the first liquid L1 supplied by the supply unit 51 in the spraying step. The quantity of the second gas G2 supplied by the supply unit 41 in the second gas treating step will be referred to as a quantity M2. The quantity M1 is larger than the quantity M2. For example, the quantity M1 is twice or larger than the quantity M2. For example, the quantity M1a is larger than the quantity M2. For example, the quantity M1a is twice or larger than the quantity M2. For example, the quantity M1b is larger than the quantity M2. For example, the quantity M1b is twice or larger than the quantity M2.

For example, each of the quantities M1, M1a, M1b, and M2 is a mass. For example, each of the quantities M1, M1a, M1b, and M2 is a volume. When each of the quantities M1, M1a, M1b, and M2 is a volume, the quantity M2 is regarded as a converted value for liquid. For example, the quantity M2 is a volume of a liquid obtained by condensing the second gas G2. For example, the quantity M2 is a volume of a liquid used for generating the second gas G2.

A time over which the first spraying step is executed will be referred to as a time T1a. A time over which the second spraying step is executed will be referred to as a time T1b. The total time of the time T1a and the time T1b will be referred to as a time T1. The time T1 corresponds to the time over which the spraying step is executed. A time over which the second gas treating step is executed will be referred to as a time T2. The time T1 is longer than the time T2. For example, the time T1a is longer than the time T2. For example, the time T1b is longer than the time T2.

The quantity M1 per unit time will be referred to as a flow rate R1. A quantity M1a per unit time will be referred to as a flow rate R1a. A quantity M1b per unit time will be referred to as a flow rate R1b. The quantity M2 per unit time will be referred to as a flow rate R2. For example, the flow rate R1 is a value obtained by dividing the quantity M1 by the time T1. For example, the flow rate R1a is a value obtained by dividing the quantity M1a by the time T1a. For example, the flow rate R1b is a value obtained by dividing the quantity M1b by the time T1b. For example, the flow rate R2 is a value obtained by dividing the quantity M2 by the time T2. The flow rate R1 is higher than the flow rate R2. For example, the flow rate R1 is twice or higher than the flow rate R2. For example, the flow rate R1a is higher than the flow rate R2. For example, the flow rate R1a is twice or higher than the flow rate R2. For example, the flow rate R1b is higher than the flow rate R2. For example, the flow rate R1b is twice or higher than the flow rate R2.

Step S21: First Pressurizing Step

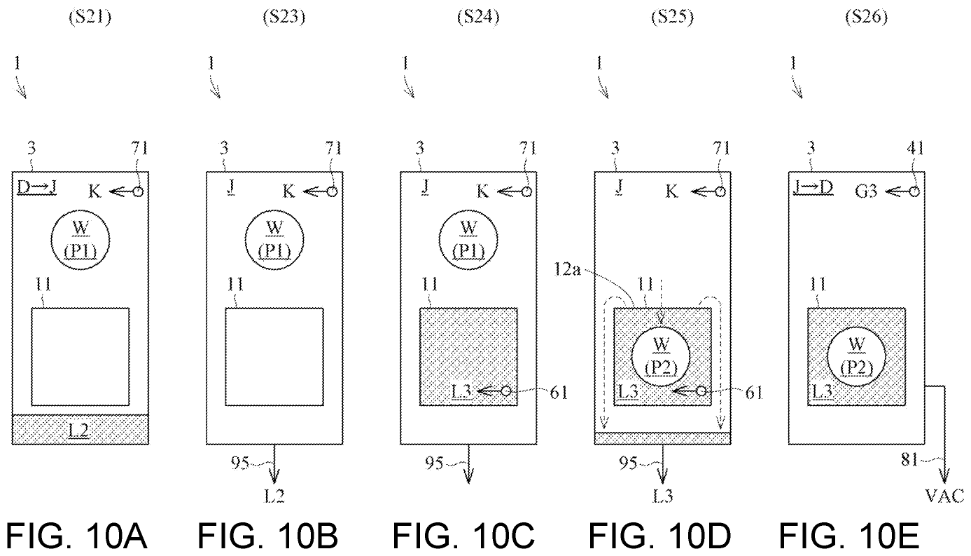

Refer to FIG. 10A. The substrate W is positioned at the first position P1. The decompression unit 81 stops operation. The supply unit 71 supplies mixed gas K to the substrate W inside the chamber 3. Accordingly, the inside of the chamber 3 is pressurized from the decompressed state D to the atmospheric pressure state J. Specifically, the inert gas of the mixed gas K quickly pressurizes the inside of the chamber 3 from the decompressed state D to the atmospheric pressure state J. In other words, the inert gas of the mixed gas K quickly raises the pressure of the gas inside the chamber 3. This is because the inert gas is unlikely to be condensed.

The organic solvent of the mixed gas K moistens the substrate W. For example, when the mixed gas K includes gas of the organic solvent, the gas of the organic solvent included in the mixed gas K is dew-condensed on the surface of the substrate W and changes to liquid of the organic solvent on the surface of the substrate W. For example, when the mixed gas K includes liquid of the organic solvent, the liquid of the organic solvent included in the mixed gas K adheres to the surface of the substrate W. Therefore, in a first pressurizing step, the substrate W does not dry. The inside of the chamber 3 shifts to the atmospheric pressure state J without causing the substrate W to dry.

In the first pressurizing step, the lifting/lowering mechanism 15 may cause the substrate W to stand still at the first position P1. Alternatively, in the first pressurizing step, the lifting/lowering mechanism 15 may vertically move the substrate W. For example, the lifting/lowering mechanism 15 may vertically move the substrate W near the first position P1. For example, the lifting/lowering mechanism 15 may vertically move the substrate W in the vertical direction Z. Alternatively, the lifting/lowering mechanism 15 may further include a mechanism (not illustrated) for swinging the substrate W. The lifting/lowering mechanism 15 may swing the substrate W by means of the mechanism. When the substrate W is vertically moved or swung, the entire substrate W favorably receives the mixed gas K. When the substrate W is vertically moved or swung, the organic solvent of the mixed gas K adheres more uniformly to the entire surface of the substrate W.

Step S22: Judging Step

The control part 101 judges whether or not the inside of the chamber 3 has shifted to the atmospheric pressure state J based on detection results of the pressure sensor 89. For example, the control part 101 acquires a measurement value of the pressure of the gas inside the chamber 3 on the basis of detection results of the pressure sensor 89. The control part 101 compares the measurement value and a standard value to each other. The standard value has been set in advance before the substrate treatment method is executed. The standard value is included in the processing information of the control part 101. When the measurement value is smaller than the standard value, the control part 101 does not judge that the inside of the chamber 3 has shifted to the atmospheric pressure state J. When the measurement value is equal to or larger than the standard value, the control part 101 judges that the inside of the chamber 3 has shifted to the atmospheric pressure state J. When the control part 101 does not judge that the inside of the chamber 3 has shifted to the atmospheric pressure state J, the procedure returns to Step S21 and continues the first pressurizing step. When the control part 101 judges that the inside of the chamber 3 has shifted to the atmospheric pressure state J, the first pressurizing step ends, and the procedure proceeds to Step S23.

Step S23: First Liquid Discharging Step

Refer to FIG. 10B. The substrate W is positioned at the first position P1. The supply unit 71 supplies the mixed gas K to the substrate W inside the chamber 3. The decompression unit 81 is at a stop. The inside of the chamber 3 is maintained in the atmospheric pressure state J. The atmosphere inside the chamber 3 includes the organic solvent derived from the mixed gas K. The liquid discharge unit 95 discharges the second liquid L2 inside the chamber 3 to the outside of the chamber 3. Specifically, the drain valve 97 opens the pipe 96 to the atmospheric air outside the chamber 3. The second liquid L2 accumulated in the chamber 3 is discharged to the outside of the chamber 3 through the pipe 96. The second liquid L2 flows from the inside of the chamber 3 to the outside of the chamber 3 through the pipe 96.

Step S24: Second Supplying Step

Refer to FIG. 10C. The substrate W is positioned at the first position P1. The supply unit 71 supplies the mixed gas K to the substrate W inside the chamber 3. The decompression unit 81 is at a stop. The inside of the chamber 3 is maintained in the atmospheric pressure state J. The atmosphere inside the chamber 3 includes the organic solvent derived from the mixed gas K. The dumping valve 92 is closed. The supply unit 61 supplies the third liquid L3 to the treatment tank 11. The treatment tank 11 stores the third liquid L3.

Step S25: Second Dipping Step

Refer to FIG. 10D. The supply unit 71 supplies the mixed gas K to the substrate W inside the chamber 3. The decompression unit 81 is at a stop. The inside of the chamber 3 is maintained in the atmospheric pressure state J. The atmosphere inside the chamber 3 includes the organic solvent derived from the mixed gas K. The lifting/lowering mechanism 15 moves the substrate W from the first position P1 to the second position P2. The substrate W is dipped into the third liquid L3 inside the treatment tank 11. The third liquid L3 washes the substrate W. For example, the third liquid L3 removes the unreacted water-repellent agent H on the substrate W. For example, the third liquid L3 also removes particles derived from the water-repellent agent H on the substrate W.

The liquid discharge unit 95 discharges the third liquid L3 inside the chamber 3 to the outside of the chamber 3. The liquid discharge unit 95 discharges the third liquid L3 which has overflowed from the treatment tank 11 to the outside of the chamber 3. Specifically, the supply unit 61 continuously supplies the third liquid L3 to the treatment tank 11. The dumping valve 92 is closed. The third liquid L3 overflows through the opening 12a of the treatment tank 11. When the third liquid L3 overflows from the treatment tank 11, the water-repellent agent which has been removed from the substrate W also overflows from the treatment tank 11. When the third liquid L3 overflows from the treatment tank 11, particles which are derived from the water-repellent agent H and have been removed from the substrate W also overflow from the treatment tank 11. The third liquid L3 which has overflowed from the treatment tank 11 is accumulated in the bottom part of the chamber 3. The drain valve 97 is opened. The pipe 96 is open to the atmospheric air outside the chamber 3. The third liquid L3 accumulated in the bottom part of the chamber 3 flows to the outside of the chamber 3 through the pipe 96.

Step S26: Atmosphere Forming Step

Refer to FIG. 10E. The substrate W is positioned at the second position P2 and is dipped into the third liquid L3 inside the treatment tank 11. The supply unit 61 stops supplying of the third liquid L3. The drain valve 97 is closed. The supply unit 71 stops supplying of the mixed gas K. The supply unit 41 supplies the treatment gas to the inside of the chamber 3. In this specification, the treatment gas supplied to the chamber 3 after the second dipping step will be suitably referred to as “a third gas G3”. The decompression unit 81 starts operation. The inside of the chamber 3 shifts from the atmospheric pressure state J to the decompressed state D. An atmosphere of the third gas G3 is formed inside the chamber 3.

Step S27: Third Gas Treating Step

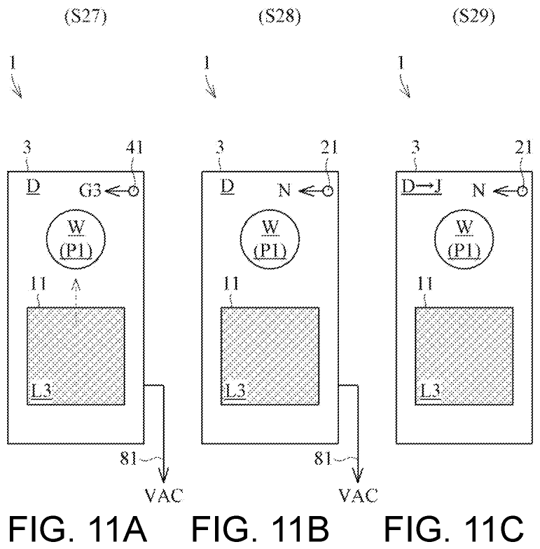

Refer to FIG. 11A. The decompression unit 81 is in operation. The inside of the chamber 3 is maintained in the decompressed state D. The supply unit 41 supplies the third gas G3 to the inside of the chamber 3. The lifting/lowering mechanism 15 moves the substrate W from the second position P2 to the first position P1. The substrate W is picked up from the third liquid L3 inside the treatment tank 11. The supply unit 41 supplies the third gas G3 to the substrate W. The gas of the organic solvent included in the third gas G3 changes to liquid of the organic solvent on the surface of the substrate W. The organic solvent derived from the third gas G3 removes the third liquid L3 on the substrate W. The liquid of the organic solvent derived from the third gas G3 covers the surface of the substrate W.

Step S28: Drying Step

Refer to FIG. 11B. The substrate W is positioned at the first position P1. The decompression unit 81 is in operation. The inside of the chamber 3 is maintained in the decompressed state D. The supply unit 41 stops supplying of the third gas G3. The supply unit 21 supplies the inert gas N to the substrate W. The inert gas N removes the organic solvent on the substrate W. The substrate W dries.

Step S29: Second Pressurizing Step

Refer to FIG. 11C. The substrate W is positioned at the first position P1. The supply unit 21 supplies the inert gas N. The decompression unit 81 stops operation. The inside of the chamber 3 is pressurized from the decompressed state D to the atmospheric pressure state J.

### 2-3. Effects of Second Embodiment

According to the second embodiment, effects similar to those of the first embodiment are exhibited. For example, particles on the substrate W can also be favorably reduced even by the substrate treatment method of the second embodiment. Moreover, according to the second embodiment, the following effects are exhibited.

The spraying step includes the first spraying step and the second spraying step. In the first spraying step, the first liquid L1 is the diluted first liquid L1a. In the first spraying step, the diluted first liquid L1a is sprayed as the first liquid L1. For this reason, the quantity of the organic solvent used in the first spraying step is favorably reduced. In the second spraying step, the first liquid L1 is the undiluted first liquid L1b. In the second spraying step, the undiluted first liquid L1b is sprayed as the first liquid L1. The undiluted first liquid L1b practically includes no water. For this reason, the undiluted first liquid L1b has a small surface tension. Thus, in the second spraying step, the undiluted first liquid L1b does not exert a significant force to the substrate W. As a result, in the second spraying step, the substrate W is favorably protected. In the second spraying step, the pattern formed on the surface of the substrate W is favorably protected.

The substrate treatment method includes the second gas treating step. The second gas treating step is executed after the water-repellency treatment step. In the second gas treating step, the inside of the chamber 3 is in the decompressed state D, and the second gas G2 is supplied to the substrate W inside the chamber 3. The second gas G2 includes gas of the organic solvent. In the second gas treating step, the entire substrate W is exposed to the second gas G2. For this reason, in the second gas treating step, the organic solvent derived from the second gas G2 quickly adheres to the entire substrate W. In the second gas treating step, the organic solvent derived from the second gas G2 uniformly adheres to the entire substrate W. Thus, in the second gas treating step, uniformity in cleanness of the substrate W throughout the entire substrate W is improved.

The quantity M1 of the first liquid L1 supplied in the spraying step is larger than the quantity M2 of the second gas G2 supplied in the second gas treating step. Thus, in the spraying step, the first liquid L1 more appropriately removes particles on the substrate W.

The time T1 of executing the spraying step is longer than the time T2 of executing the second gas treating step. Thus, in the spraying step, particles on the substrate W are more favorably removed.

The flow rate R1 of the first liquid L1 in the spraying step is higher than the flow rate R2 of the second gas G2 in the second gas treating step. Thus, in the spraying step, the first liquid L1 more appropriately removes particles on the substrate W.

The substrate treatment method includes the first pressurizing step and the first liquid discharging step. The first pressurizing step is executed after the spraying step. In the first pressurizing step, the inside of the chamber 3 is pressurized from the decompressed state D to the atmospheric pressure state J. The first liquid discharging step is executed after the first pressurizing step. In the first liquid discharging step, the inside of the chamber 3 is maintained in the atmospheric pressure state J, and the second liquid L2 is discharged to the outside of the chamber 3. When the inside of the chamber 3 is in the atmospheric pressure state J, the pressure of the gas inside the chamber 3 is close to the pressure of gas outside the chamber 3. For this reason, in the first liquid discharging step, it is easy to discharge the second liquid L2 inside the chamber 3 to the outside of the chamber 3.

In the first liquid discharging step, the pipe 96 is open to the atmospheric air outside the chamber 3. The pipe 96 communicates with and is connected to the chamber 3. As described above, in the first liquid discharging step, the inside of the chamber 3 is in the atmospheric pressure state J. For this reason, in the first liquid discharging step, due to the dead weight of the second liquid L2, the second liquid L2 flows from the inside of the chamber 3 to the outside of the chamber 3 through the pipe 96. In the first liquid discharging step, the second liquid L2 naturally flows from the inside of the chamber 3 to the outside of the chamber 3 through the pipe 96. In the first liquid discharging step, it is not necessary to forcibly send the second liquid L2 from the inside of the chamber 3 to the outside of the chamber 3. Thus, in the first liquid discharging step, it is easy to discharge the second liquid L2 inside the chamber 3 to the outside of the chamber 3 through the pipe 96.

In the first pressurizing step, the mixed gas K is supplied to the substrate W inside the chamber 3. The mixed gas K includes an organic solvent and inert gas. For this reason, in the first pressurizing step, the substrate W does not dry. In the first pressurizing step, the inside of the chamber 3 is quickly pressurized from the decompressed state D to the atmospheric pressure state J without causing the substrate W inside the chamber 3 to dry.

The mixed gas includes at least any of gas of the organic solvent and liquid of the organic solvent. For this reason, the organic solvent derived from the mixed gas K favorably moistens the substrate W. Thus, the mixed gas K favorably prevents the substrate from drying.

The substrate treatment method includes the second dipping step. The second dipping step is executed after the first liquid discharging step. In the second dipping step, the substrate W is dipped into the third liquid L3 stored in the treatment tank 11. For this reason, in the second dipping step, the substrate W receives a large quantity of the third liquid L3. In the second dipping step, the third liquid L3 more favorably removes particles on the substrate W. Thus, particles on the substrate W are more favorably reduced. As a result, the cleanness of the substrate W is more favorably improved. The treatment quality of the substrate W is more favorably improved.

The atmosphere inside the chamber 3 includes an organic solvent until the substrate W is dipped into the third liquid L3 after the first pressurizing step. For this reason, the organic solvent included in the atmosphere inside the chamber 3 moistens the substrate W until the substrate W is dipped into the third liquid L3 after the first pressurizing step. Thus, the substrate W does not dry until the second dipping step after the first pressurizing step. The substrate W does not dry after the spraying step and before the second dipping step. Therefore, in the second dipping step, the substrate W is treated with appropriate quality.

The third liquid L3 is a diluted organic solvent. For this reason, the third liquid L3 appropriately removes particles on the substrate W.

The disclosure is not limited to the first and second embodiments and can be modified and performed as described below.

(1) In the first and second embodiments, the emission part 52 includes the shower head nozzles. However, the disclosure is not limited thereto. For example, the emission part 52 may include the two-fluid nozzles. For example, the emission part 52 may include at least any of the shower head nozzles and the two-fluid nozzles. For example, the two-fluid nozzles of the emission part 52 have substantially the same structures as the structures of the two-fluid nozzles of the emission part 72. For example, the two-fluid nozzles of the emission part 52 inject at least any of droplets of the first liquid L1 and mist of the first liquid L1 together with the inert gas. Thus, the two-fluid nozzles of the emission part 52 favorably spray the first liquid L1.

(2) In the second embodiment, the spraying step includes the first spraying step and the second spraying step. However, the disclosure is not limited thereto. For example, in the spraying step, any of the first spraying step and the second spraying step may be omitted. For example, the spraying step may include at least any of the first spraying step and the second spraying step.

(3) In the second embodiment, the pipe 96 of the liquid discharge unit 95 communicates with and is connected to the chamber 3. However, the disclosure is not limited thereto. For example, the pipe 96 may communicate with and be connected to the treatment tank 11. Specifically, the first end of the pipe 96 may be connected to the treatment tank 11. In this modification embodiment, when the pipe 96 is open to the atmospheric air outside the chamber 3, the treatment liquid inside the treatment tank 11 is discharged to the outside of the chamber 3 through the pipe 96.

(4) In the second embodiment, the third liquid L3 is a diluted organic solvent. However, the disclosure is not limited thereto. For example, the third liquid L3 may be deionized water (DIW). Even when the third liquid L3 is deionized water, the third liquid L3 appropriately removes particles on the substrate W.

(5) In the first and second embodiments, the constitutions of the supply units 21, 31, 41, 51, 61, and 71 have been described as examples. However, the disclosure is not limited thereto. The constitutions of the supply units 21, 31, 41, 51, 61, and 71 may be suitably changed.

In the first and second embodiments, the inert gas N, the water-repellent agent H, the first gas G1, the first liquid L1, and the mixed gas K are emitted from the emission parts 22, 32, 42, 52, and 72 different from each other. However, the disclosure is not limited thereto. At least two of the inert gas N, the water-repellent agent H, the first gas G1, the first liquid L1, and the mixed gas K may be emitted from the same emission part.

In the second embodiment, the diluted first liquid L1a and the undiluted first liquid L1b are emitted from the emission parts 52a and 52b different from each other. However, the disclosure is not limited thereto. The diluted first liquid L1a and the undiluted first liquid L1b may be emitted from the same emission part.

The supply unit 61 supplies the generated third liquid L3 to the treatment tank 11. However, the disclosure is not limited thereto. The supply unit 61 may generate the third liquid L3 inside the treatment tank 11. For example, the supply unit 61 may individually supply the undiluted organic solvent and deionized water to the treatment tank 11.

The emission part 72 (two-fluid nozzles) generates the mixed gas K. However, the disclosure is not limited thereto. The emission part 72 may not generate the mixed gas K. For example, the emission part 72 may communicate with and be connected to a supply source storing the mixed gas K. For example, the supply source storing the mixed gas K may also generate the mixed gas K. For example, the supply source storing the mixed gas K may generate the mixed gas K by mixing vapor of the organic solvent and the inert gas.

(6) In the first and second embodiments, procedures of the substrate treatment methods have been described as examples. However, the disclosure is not limited thereto. The procedure of the substrate treatment method may be suitably changed.

For example, the substrate treatment methods of the first and second embodiments include the first dipping step. However, the disclosure is not limited thereto. The first dipping step may be omitted.

For example, in the second embodiment, the supply unit 71 supplies the mixed gas K to the chamber 3 until the second dipping step after the first pressurizing step. However, the disclosure is not limited thereto. For example, the supply unit 71 may supply the mixed gas K to the inside of the chamber 3 until the substrate W is dipped into the third liquid L3 inside the treatment tank 11 after the first pressurizing step. Further, the supply unit 71 may stop supplying of the mixed gas K after the substrate W is dipped into the third liquid L3 inside the treatment tank 11. According to this modification embodiment, the atmosphere inside the chamber 3 favorably includes the organic solvent of the mixed gas K until the substrate W is dipped into the third liquid L3 inside the treatment tank 11 after the first pressurizing step. For this reason, the atmosphere inside the chamber 3 favorably includes the organic solvent of the mixed gas K until the second dipping step after the first pressurizing step even by this modification embodiment.

Alternatively, after the first pressurizing step, the supply unit 71 may stop supplying of the mixed gas K. For example, in the first liquid discharging step, the second supplying step, and the second dipping step, the supply unit 71 may stop supplying of the mixed gas K. In the first pressurizing step, an atmosphere of the mixed gas K is formed inside the chamber 3. In the first liquid discharging step, the second supplying step, and the second dipping step, the inside of the chamber 3 is not decompressed. In the first liquid discharging step, the second supplying step, and the second dipping step, the gas inside the chamber 3 is not discharged to the outside of the chamber 3. For this reason, the atmosphere of the mixed gas K remains inside the chamber 3 until the second dipping step after the first pressurizing step. Thus, the atmosphere inside the chamber 3 favorably includes the organic solvent of the mixed gas K until the second dipping step after the first pressurizing step even by this modification embodiment.

(7) The first to third embodiments and each of the modification embodiments described in the foregoing (1) to (6) may be suitably changed by further replacing or combining each constituent with a constituent of other modification embodiments.

The disclosure can be performed in other specific forms without departing from the spirit and the essence thereof, and therefore the appended claims should be referred to instead of the foregoing description so as to indicate the scope of the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

### REFERENCE SIGNS LIST

1 Substrate treatment device
3 Chamber
11 Treatment tank
31 Supply unit (second supply unit)
41 Supply unit (first supply unit)
51 Supply unit (spray unit)
52 Emission part
81 Decompression unit
89 Pressure sensor
95 Liquid discharge unit
96 Pipe (liquid discharge tube)
101 Control part
D Decompressed state
G1 First gas
G2 Second gas
H Water-repellent agent
J Atmospheric pressure state
K Mixed gas
L1 First liquid
L1a Diluted first liquid (diluted organic solvent)
L1b Undiluted first liquid (undiluted organic solvent)
L2 Second liquid
L3 Third liquid
M1 Quantity of first liquid supplied in spraying step
M2 Quantity of second gas supplied in second gas treating step
P1 First position
P2 Second position
T1 Time of executing spraying step
T2 Time of executing second gas treating step
W Substrate

What is claimed is:

1. A substrate treatment method for simultaneously treating a plurality of substrates accommodated in one chamber, the substrate treatment method comprising:
a first gas treating step of supplying a first gas including gas of an organic solvent to the substrate inside the chamber in a state in which the inside of the chamber is decompressed;
a water-repellency treatment step of supplying a water-repellent agent to the substrate inside the chamber in a state in which the inside of the chamber is decompressed after the first gas treating step; and
a spraying step of spraying a first liquid including liquid of an organic solvent over the substrate inside the chamber in a state in which the inside of the chamber is decompressed after the water-repellency treatment step.

2. The substrate treatment method according to claim 1,
wherein in the spraying step, at least any of droplets of the first liquid and mist of the first liquid is sprayed.

3. The substrate treatment method according to claim 1,
wherein in the spraying step, the first liquid is sprayed through at least any of shower head nozzles and two-fluid nozzles.

4. The substrate treatment method according to claim 1,
wherein in the spraying step, the substrate is further vertically moved or swung inside the chamber.

5. The substrate treatment method according to claim 1,
wherein the spraying step includes at least any of a first spraying step and a second spraying step,
wherein in the first spraying step, a diluted organic solvent is sprayed as the first liquid, and
wherein in the second spraying step, an undiluted organic solvent is sprayed as the first liquid.

6. The substrate treatment method according to claim 1 further comprising:
a second gas treating step of supplying a second gas including gas of an organic solvent to the substrate inside the chamber in a state in which the inside of the chamber is decompressed after the water-repellency treatment step.

7. The substrate treatment method according to claim 6,
wherein a quantity of the first liquid supplied in the spraying step is larger than a quantity of the second gas supplied in the second gas treating step.

8. The substrate treatment method according to claim 6,
wherein a time over which the spraying step is executed is longer than a time over which the second gas treating step is executed.

9. The substrate treatment method according to claim 1 further comprising:
a first dipping step of dipping the substrate into a second liquid stored in a treatment tank installed inside the chamber before the first gas treating step,
wherein in the first gas treating step, the water-repellency treatment step, and the spraying step, the substrate is positioned above the treatment tank.

10. The substrate treatment method according to claim 9 further comprising:
a first pressurizing step of pressurizing the inside of the chamber from a decompressed state to an atmospheric pressure state after the spraying step; and
a first liquid discharging step of maintaining the inside of the chamber in an atmospheric pressure state and discharging the second liquid to the outside of the chamber after the first pressurizing step.

11. The substrate treatment method according to claim 10,
wherein in the first liquid discharging step, a liquid discharge tube which communicates with and is connected to any of the chamber and the treatment tank is open to atmospheric air outside the chamber, and the second liquid is discharged to the outside of the chamber through the liquid discharge tube.

12. The substrate treatment method according to claim 10,
wherein in the first pressurizing step, mixed gas including an organic solvent and inert gas is supplied to a substrate inside the chamber.

13. The substrate treatment method according to claim 12,
wherein the mixed gas includes at least any of gas of the organic solvent and liquid of the organic solvent.

14. The substrate treatment method according to claim 10 further comprising:
a second dipping step of dipping the substrate into a third liquid stored in the treatment tank after the first pressurizing step.

15. The substrate treatment method according to claim 14,
wherein an atmosphere inside the chamber includes an organic solvent until the substrate is dipped into the third liquid from the first pressurizing step.

16. The substrate treatment method according to claim 14,
wherein the third liquid is any of a diluted organic solvent and deionized water.

17. A substrate treatment device comprising:
a chamber that accommodates a plurality of substrates;
a decompression unit that decompresses the inside of the chamber;
a first supply unit that supplies a first gas including gas of an organic solvent to the substrate inside the chamber;
a second supply unit that supplies a water-repellent agent to the substrate inside the chamber;
a spray unit that sprays a first liquid including liquid of an organic solvent over the substrate inside the chamber; and
a control part that controls the decompression unit, the first supply unit, the second supply unit, and the spray unit to execute first gas treatment, water-repellency treatment, and spraying treatment,
wherein in the first gas treatment, the first supply unit supplies the first gas to the substrate in a state in which the inside of the chamber is decompressed by the decompression unit,
wherein in the water-repellency treatment, the second supply unit supplies the water-repellent agent to the substrate in a state in which the inside of the chamber is decompressed by the decompression unit, and
wherein in the spraying treatment, the spray unit sprays the first liquid over the substrate in a state in which the inside of the chamber is decompressed by the decompression unit.
